(19) United States
(12) Patent Application Publication
(10) Pub. No.: US 2024/0288678 A1
(43) Pub. Date: Aug. 29, 2024

(54) EXPOSURE METHOD, EXPOSURE DEVICE, AND METHOD OF FORMING OPTICALLY-ANISOTROPIC LAYER

(71) Applicant: FUJIFILM Corporation, Tokyo (JP)

(72) Inventors: Hirotoshi ANDO, Minamiashigara-shi (JP); Takehiko HARASAWA, Minamiashigara-shi (JP); Satoshi NAGANO, Minamiashigara-shi (JP); Yasuhiro SEKIZAWA, Minamiashigara-shi (JP)

(73) Assignee: FUJIFILM Corporation, Tokyo (JP)

(21) Appl. No.: 18/643,009

(22) Filed: Apr. 23, 2024

Related U.S. Application Data
(63) Continuation of application No. PCT/JP2022/041520, filed on Nov. 8, 2022.

(30) Foreign Application Priority Data
Nov. 11, 2021 (JP) 2021-184094

(51) Int. Cl. G02B 26/00; G02B 5/00; G02B 27/28; G03F 7/00

(52) U.S. Cl. CPC G02B 26/00; G02B 5/001; G02B 27/286; G03F 7/70258; G03F 7/70316; G03F 7/70366

(57) ABSTRACT

An object is to provide an exposure method and an exposure device for obtaining a photo-alignment film where the accuracy of an alignment pattern is high, and a method of forming an optically-anisotropic layer. In a case where linearly polarized light is focused in a ring shape with an optical member and a film including a compound having a photo-aligned group is exposed, while rotating a polarization direction of the polarized light, the film and the optical member are relatively moved in a direction tilted with respect to an optical axis of the optical member.

### CROSS-REFERENCE TO RELATED APPLICATIONS

This application is a Continuation of PCT International Application No. PCT/JP2022/041520 filed on Nov. 8, 2022, which claims priority under 35 U.S.C. § 119(a) to Japanese Patent Application No. 2021-184094 filed on Nov. 11, 2021. The above applications are hereby expressly incorporated by reference, in their entirety, into the present application.

### BACKGROUND OF THE INVENTION

### 1. Field of the Invention

The present invention relates to an exposure method and an exposure device for exposing a film including a compound having a photo-aligned group, and a method of forming an optically-anisotropic layer using this exposure method.

### 2. Description of the Related Art

Currently, polarized light is used for forming an alignment film or the like used in an optical element, a liquid crystal display device, or the like.

As an apparatus for manufacturing an optical element using polarized light, for example, an apparatus described in JP2015-532468A is used.

The apparatus described in JP2015-532468A includes: a polarization selector stage configured to vary polarization of light from a light source among a plurality of polarized light components; a focusing element configured to focus the light from the light source into a spot at a focal plane thereof; and a scanning stage configured to support and scan a polarization-sensitive recording medium.

In this apparatus, the scanning stage scans the spot in at least two dimensions along a surface of the polarization-sensitive recording medium arranged proximate to the focal plane such that neighboring scans of the spot spatially overlap. In the apparatus described in JP2015-532468A, a desired alignment pattern is formed with the above-described configuration.

The polarization selector stage and the scanning stage are configured to perform the varying of the polarization and the scanning of the spot independently of each other.

### SUMMARY OF THE INVENTION

In the apparatus described in JP2015-532468A, the spot is scanned using the scanning stage in at least two dimensions along the polarization-sensitive recording medium. The type of moving the light from the light source using the scanning stage in two dimensions, that is, on the plane for exposure to any pattern as in the apparatus described in JP2015-532468A is called a direct drawing type. The type of moving the light itself from the light source on the plane for exposure to any pattern is also called the direct drawing type.

The apparatus described in JP2015-532468A moves the scanning stage such that the spot is scanned along the surface of the recording medium. Therefore, in the case of an arc pattern, in a case where the arc of the pattern to be formed is small, there is a problem in that the pattern accuracy decreases, for example, due to the occurrence of undulation depending on the resolution of the scanning stage or the occurrence of undulation on the arc pattern caused by the straightness and the positioning accuracy of the scanning stage itself.

An object of the present invention is to provide an exposure method and an exposure device for obtaining a photo-alignment film where the accuracy of an alignment pattern is high, and a method of forming an optically-anisotropic layer.

In order to achieve the above-described object, the present invention has the following configurations.
[1] An exposure method comprising:
focusing linearly polarized light in a ring shape with an optical member and exposing a film including a compound having a photo-aligned group,
in which while rotating a polarization direction of the linearly polarized light,
the film and the optical member are relatively moved in a direction tilted with respect to an optical axis of the optical member.
[2] The exposure method according to [1],
in which while maintaining an angle between a normal line of the film and the optical axis of the optical member, the film and the optical member are relatively moved in the direction tilted with respect to the optical axis of the optical member.
[3] The exposure method according to [1],
in which while maintaining a normal line of the film and the optical axis of the optical member in parallel, the film and the optical member are relatively moved in the direction tilted with respect to the optical axis of the optical member.
[4] The exposure method according to any one of [1] to [3],
in which the optical member includes an axicon lens or an axicon mirror.
[5] The exposure method according to [4],
in which in a case where an angle between a bottom surface and a generatrix of a cone configuring the axicon lens or the axicon mirror is represented by θ and a refractive index of a material for forming the axicon lens is represented by n,
an angle α between the relative movement direction of the film and the optical member and an optical axis of the axicon lens satisfies

$$α < {sin}^{- 1} ( n \cdot sin θ ) - θ$$

or
an angle α between the relative movement direction of the film and the optical member and an optical axis of the axicon mirror satisfies

$$α < 2 θ .$$

[6] An exposure method comprising:
focusing linearly polarized light in a ring shape with an optical member and exposing a film including a compound having a photo-aligned group,
in which while rotating a polarization direction of the linearly polarized light,
the film and the optical member are relatively moved in an optical axis direction of the optical member in a state where a normal line of the film is tilted with respect to an optical axis of the optical member.
[7] The exposure method according to [6],
in which while maintaining an angle between the normal line of the film and the optical axis of the optical member, the film and the optical member are relatively moved in the optical axis direction of the optical member.
[8] The exposure method according to [6] or [7],
in which the optical member includes an axicon lens or an axicon mirror.
[9] The exposure method according to [8],
in which in a case where an angle between a bottom surface and a generatrix of a cone configuring the axicon lens or the axicon mirror is represented by θ and a refractive index of a material for forming the axicon lens is represented by n,
an angle β between the normal line of the film and an optical axis of the axicon lens satisfies

$$β < 90 s - {sin}^{- 1} ( n \cdot sin θ ) + θ$$

or
an angle β between the normal line of the film and an optical axis of the axicon mirror satisfies

$$β < 90 - 2 θ .$$

[10] An exposure method comprising:
focusing linearly polarized light in a ring shape with an optical member and exposing a film containing a compound having a photo-aligned group,
in which the linearly polarized light is incident into the optical member from a direction tilted with respect to an optical axis of the optical member, and
while rotating a polarization direction of the linearly polarized light,
the film and the optical member are relatively moved in the incidence direction of the linearly polarized light into the optical member.
[11] The exposure method according to [10],
in which while maintaining an angle between a normal line of the film and the incidence direction of the linearly polarized light into the optical member, the film and the optical member are relatively moved in the incidence direction of the linearly polarized light into the optical member.
[12] The exposure method according to [10],
in which while maintaining a normal line of the film and the incidence direction of the linearly polarized light into the optical member in parallel, the film and the optical member are relatively moved in the incidence direction of the linearly polarized light into the optical member.
[13] The exposure method according to any one of [10] to [12],
in which the optical member includes an axicon lens or an axicon mirror.
[14] The exposure method according to [13],
wherein in a case where an angle between a bottom surface and a generatrix of a cone configuring the axicon lens or the axicon mirror is represented by θ and a refractive index of a material for forming the axicon lens is represented by n,
an angle γ between an incidence direction of the linearly polarized light into the optical member and an optical axis of the axicon lens satisfies

$${sin}^{- 1} ( n \cdot sin ( θ + γ ) ) - θ - γ > 0$$

or
an angle γ between an incidence direction of the linearly polarized light into the optical member and an optical axis of the axicon mirror satisfies

$$γ < 2 θ .$$

[15] The exposure method according to any one of [1] to [14],
in which in the relative movement of the film and the optical member, a movement speed is continuously changed.
[16] The exposure method according to any one of [1] to [15],
in which in the rotation in the polarization direction of the linearly polarized light, a rotation speed is continuously changed.
[17] The exposure method according to any one of [1] to [16],
in which the linearly polarized light incident into the optical member is parallel light.
[18] The exposure method according to any one of [1] to [17],
in which the linearly polarized light includes ultraviolet light.
[19] An exposure device comprising:
a light source unit that emits linearly polarized light;
a rotating unit that rotates a polarization direction of the linearly polarized light emitted from the light source unit;
an optical member that focuses the linearly polarized light transmitted through the rotating unit in a ring shape;
a stage that supports a film including a compound having a photo-aligned group and is disposed to be spaced from the optical member in an optical axis direction of the optical member; and
a moving unit that moves the stage in a direction tilted with respect to an optical axis of the optical member.
[20] The exposure device according to [19],
in which the moving unit moves the stage while maintaining an angle between a normal line of the film and the optical axis of the optical member.
[21] The exposure device according to [19],
in which the moving unit moves the stage while maintaining a normal line of the film and the optical axis of the optical member in parallel.
[22] The exposure device according to any one of [19] to [21],
in which the optical member includes an axicon lens or an axicon mirror.
[23] The exposure device according to [22],
in which in a case where an angle between a bottom surface and a generatrix of a cone configuring the axicon lens or the axicon mirror is represented by θ and a refractive index of a material for forming the axicon lens is represented by n,
an angle α between the movement direction of the film by the moving unit and an optical axis of the axicon lens satisfies

$$α < {sin}^{- 1} ( n \cdot sin θ ) - θ$$

or
an angle α between the movement direction of the film by the moving unit and an optical axis of the axicon mirror satisfies

$$α < 2 θ .$$

[24] An exposure device comprising:
a light source unit that emits linearly polarized light;
a rotating unit that rotates a polarization direction of the linearly polarized light emitted from the light source unit;
an optical member that focuses the linearly polarized light transmitted through the rotating unit in a ring shape;
a stage that supports a film including a compound having a photo-aligned group in a state where a normal line of the film is tilted with respect to an optical axis of the optical member and is disposed to be spaced from the optical member in an optical axis direction of the optical member; and
a moving unit that moves the stage in the optical axis direction of the optical member.
[25] The exposure device according to [24],
in which the moving unit moves the stage while maintaining an angle between the normal line of the film and the optical axis of the optical member.
[26] The exposure device according to or [25],
in which the optical member includes an axicon lens or an axicon mirror.
[27] The exposure device according to [26],
in which in a case where an angle between a bottom surface and a generatrix of a cone configuring the axicon lens or the axicon mirror is represented by θ and a refractive index of a material for forming the axicon lens is represented by n,
an angle β between the normal line of the film and an optical axis of the axicon lens satisfies

$$β < 90 - {sin}^{- 1} ( n \cdot sin θ ) + θ$$

or
an angle β between the normal line of the film and an optical axis of the axicon mirror satisfies

$$β < 90 - 2 θ .$$

[28] An exposure device comprising:
a light source unit that emits linearly polarized light;
a rotating unit that rotates a polarization direction of the linearly polarized light emitted from the light source unit;
an optical member that is disposed to be tilted with respect to an optical axis of the light source unit and focuses the linearly polarized light transmitted through the rotating unit in a ring shape;
a stage that supports a film including a compound having a photo-aligned group and is disposed to be spaced from the optical member in an optical axis direction of the optical member; and
a moving unit that moves the stage in a direction parallel to the optical axis of the light source unit.
[29] The exposure device according to [28],
in which the moving unit moves the stage while maintaining an angle between a normal line of the film and the optical axis of the light source unit.
[30] The exposure device according to [28],
in which the moving unit moves the stage while maintaining a normal line of the film and the optical axis of the light source unit in parallel.
[31] The exposure device according to any one of [28] to [30],
in which the optical member includes an axicon lens or an axicon mirror.
[32] The exposure device according to [31],
in which in a case where an angle between a bottom surface and a generatrix of a cone configuring the axicon lens or the axicon mirror is represented by θ and a refractive index of a material for forming the axicon lens is represented by n,
an angle γ between an incidence direction of the linearly polarized light into the optical member and an optical axis of the axicon lens satisfies

$${sin}^{- 1} ( n \cdot sin ( θ + γ ) ) - θ - γ > 0$$

or
an angle γ between an incidence direction of the linearly polarized light into the optical member and an optical axis of the axicon mirror satisfies

$$γ < 2 θ .$$

[33] The exposure device according to any one of [19] to [32], further comprising:
an optical element that converts the linearly polarized light incident into the optical member into parallel light.
[34] The exposure device according to any one of [19] to [33],
in which the linearly polarized light emitted from the light source unit includes ultraviolet light.
[35] The exposure device according to any one of [19] to [34], wherein the light source unit includes a laser light source.
[36] The exposure device according to any one of [19] to [35], further comprising:
a shutter that is provided between the light source unit and the stage and blocks the linearly polarized light emitted from the light source unit.
[37] A method of forming an optically-anisotropic layer, the method comprising:
applying a composition including a liquid crystal compound to a photo-alignment film obtained using the exposure method according to any one of [1] to [18] and aligning the liquid crystal compound to form an optically-anisotropic layer.

According to the present invention, it is possible to provide an exposure method and an exposure device for obtaining a photo-alignment film where the accuracy of an alignment pattern is high, and a method of forming an optically-anisotropic layer.

### BRIEF DESCRIPTION OF THE DRAWINGS

FIG. 1 is a schematic diagram showing an example of an exposure device according to a first aspect of the present invention.

FIG. 2 is a schematic diagram showing an example of an optical member of the exposure device shown in FIG. 1.

FIG. 3 is a schematic diagram showing an example of an exposure pattern formed by an exposure device in the related art.

FIG. 4 is a schematic diagram showing an example of an exposure pattern formed by the exposure device shown in FIG. 1.

FIG. 5 is a schematic diagram showing another example of an operation by the exposure device shown in FIG. 1.

FIG. 6 is a schematic diagram showing an elliptic conical axicon lens.

FIG. 7 is a schematic diagram showing an example of an exposure pattern using the elliptic conical axicon lens in the exposure device shown in FIG. 1.

FIG. 8 is a schematic diagram showing a part of an example of an exposure device according to a second aspect of the present invention.

FIG. 9 is a schematic diagram showing an example of an exposure pattern formed by the exposure device shown in FIG. 8.

FIG. 10 is a schematic diagram showing a part of an example of an exposure device according to a third aspect of the present invention.

FIG. 11 is a schematic diagram showing an example of an exposure pattern formed by the exposure device shown in FIG. 10.

FIG. 12 is a schematic diagram showing another example of an optical member that can be used in the exposure device according to the present invention.

FIG. 13 is a schematic plan view showing an example of an optical element manufactured using an exposure method according to an embodiment of the present invention.

FIG. 14 is a schematic cross-sectional view showing the example of the optical element manufactured using the exposure method according to the embodiment of the present invention.

FIG. 15 is a schematic diagram showing the optical element manufactured using the exposure method according to the embodiment of the present invention.

FIG. 16 is a schematic diagram showing the optical element manufactured using the exposure method according to the embodiment of the present invention.

FIG. 17 is a schematic diagram showing the optical element manufactured using the exposure method according to the embodiment of the present invention.

FIG. 18 is a schematic cross-sectional view showing an example of a reflective optical element manufactured using the exposure method according to the embodiment of the present invention.

FIG. 19 is a schematic diagram showing the example of the reflective optical element manufactured using the exposure method according to the embodiment of the present invention.

FIG. 20 is a schematic diagram showing the example of the reflective optical element manufactured using the exposure method according to the embodiment of the present invention.

FIG. 21 is a schematic diagram showing the example of the reflective optical element manufactured using the exposure method according to the embodiment of the present invention.

### DESCRIPTION OF THE PREFERRED EMBODIMENTS

Hereinafter, an exposure method, an exposure device, and a method of forming an optically-anisotropic layer according to the present invention will be described in detail based on preferred embodiments shown in the accompanying drawings.

The drawings described below are exemplary drawings for describing the present invention, and the present invention is not limited to the drawings described below.

In the following description, a numerical range indicated by the expression “to” includes numerical values described on both sides. For example, in a case where & is a numerical value α to a numerical value β, the range & is a range including the numerical value α and the numerical value β, which is expressed by a mathematical symbol α≤&≤εβ.

Unless specified otherwise, the meaning of an angle such as “an angle represented by a specific numerical value”, “parallel”, “perpendicular”, or “orthogonal” includes a case where an error range is generally allowable in the technical field.

### (First Aspect)

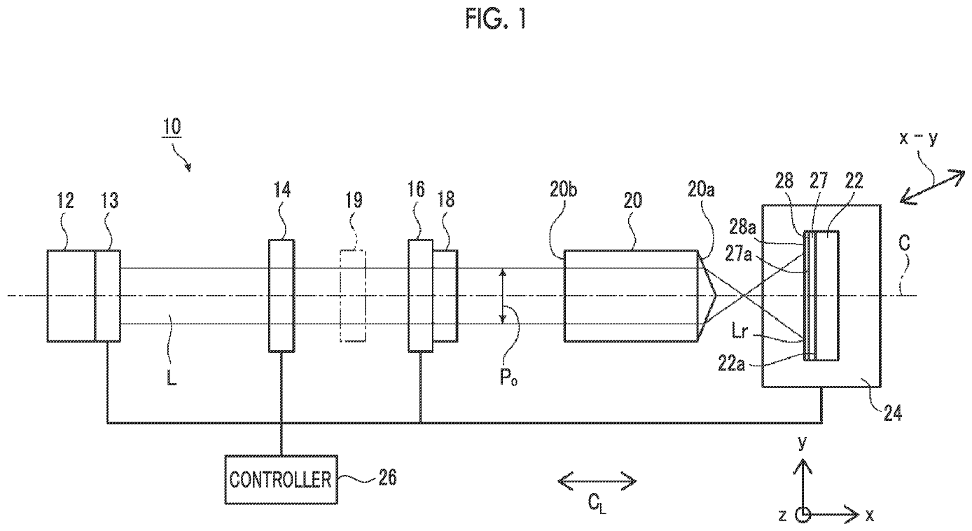

FIG. 1 is a schematic diagram showing an example of a first aspect of the exposure device according to the present invention that implements a first aspect of the exposure method according to the present invention.

In the following description, the first aspect of the exposure method according to the present invention and the first aspect of the exposure device according to the present invention will be collectively referred to as the first aspect of the present invention.

An exposure device 10 shown in FIG. 1 is a device for focusing linearly polarized light in a ring shape with an optical member 20 and exposing a film 28 including a compound having a photo-aligned group. In the following description, “the film 28 including the compound having a photo-aligned group” will be simply referred to as “film 28”.

The exposure device 10 includes a light source unit 12, a shutter 14, a rotating unit 16, a λ/2 plate 18, the optical member 20, a stage 22, a moving unit 24, and a controller 26. Operations of the light source unit 12, the shutter 14, the rotating unit 16, and the moving unit 24 are controlled by the controller 26.

The light source unit 12, the shutter 14, the rotating unit 16, the λ/2 plate 18, the optical member 20, and the stage 22 are disposed in this order along an optical axis C of the optical member 20.

The light source unit 12 emits linearly polarized light and includes, for example, a light source portion 13 that emits laser light L of linearly polarized light. In this case, the light source portion 13 is a laser light source.

The laser light L emitted from the light source portion 13 does not need to be linearly polarized light. In a case where the laser light L is not linearly polarized light, the laser light L is converted into the laser light L of linearly polarized light before being incident into the optical member 20. Therefore, an optical element such as a polarizer (not shown) or a λ/4 plate is provided in an optical path of the laser light L to change the polarization state such that the laser light L of linearly polarized light is obtained.

In addition, the light source portion 13 is not limited to the laser light source that emits the laser light L. In a case where the light emitted from the light source portion 13 is unpolarized light other than laser light, for example, white light, the polarization state is changed, for example, using a polarizer (not shown) to obtain linearly polarized light. In a case where the light emitted from the light source portion 13 is circularly polarized light, the polarization state is changed, for example, using a λ/4 plate (not shown) to obtain linearly polarized light. In this case, the light source unit 12 is configured to include a polarizer or a λ/4 plate that converts the light into linearly polarized light.

For example, the polarizer or the λ/4 plate is integrated with the light source portion 13 and is disposed on an emission surface of the light source portion 13. However, the present invention is not limited to this configuration. The polarizer or the λ/4 plate may be separately provided as long as it is disposed on the emission surface side of the light source portion 13. In this case, the polarizer or the λ/4 plate may be disposed on an incident surface side of the λ/2 plate 18 in an optical axis direction C_{L} of the optical member 20. With this configuration, the light source unit 12 emits linearly polarized light.

The light source unit 12 (light source portion 13) emits light having a wavelength to which the film 28 including the compound having a photo-aligned group to be exposed has sensitivity.

For example, in a case where the film 28 to be exposed has sensitivity to ultraviolet light and is exposed to ultraviolet light, the linearly polarized light emitted from the light source unit 12 includes ultraviolet light. In this case, for example, the light source portion 13 that emits the laser light L including ultraviolet light is used.

Here, the ultraviolet light is light having a wavelength of 250 to 430 nm.

In addition, the exposure device 10 can also be configured to include an optical element 19 that converts the linearly polarized light emitted from the light source unit 12 into parallel light. The optical element 19 converts the laser light L into parallel light. The optical element 19 that converts the linearly polarized light into parallel light is not particularly limited as long as it can convert the linearly polarized light into parallel light. For example, a collimating lens is used.

The optical element 19 is provided between the light source unit 12 and the λ/2 plate 18, for example, in the optical axis direction C_{L} of the optical member 20. However, the disposition position of the optical element 19 is not particularly limited as long as it is provided between the light source unit 12 and the optical member 20.

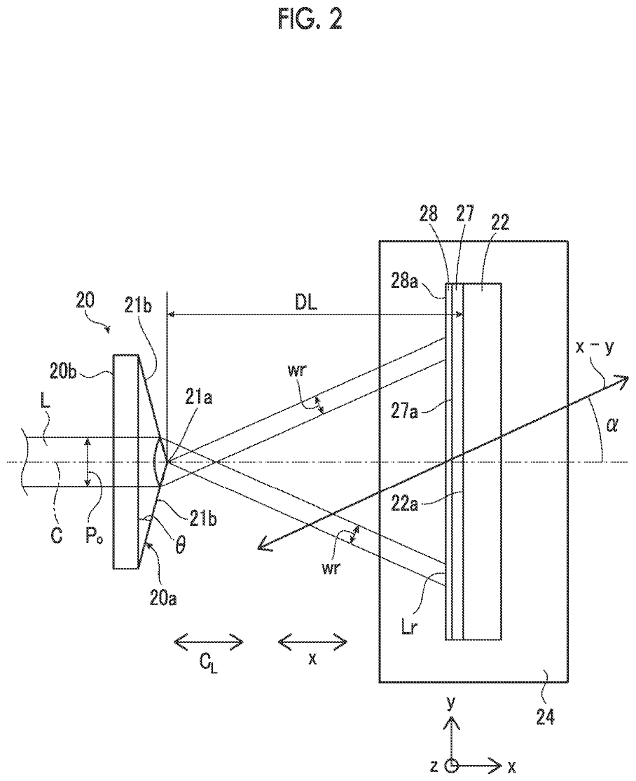

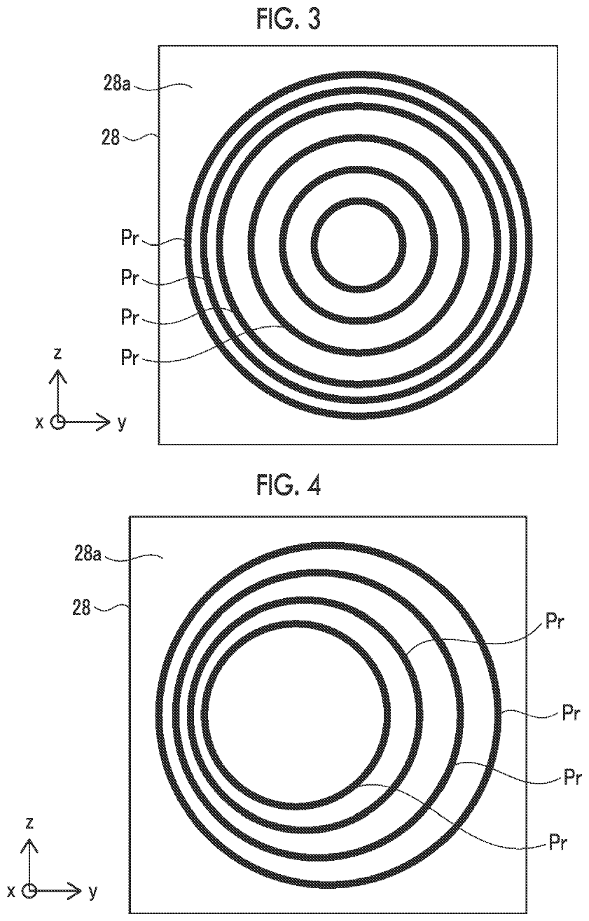

By providing the optical element 19 that converts the linearly polarized light into parallel light, a width wr of light Lr having a ring shape shown in FIG. 2 below can be made more uniform, and the width of an exposure pattern Pr shown in FIG. 3 can be made more uniform. Therefore, the exposure can be performed with high accuracy.

The shutter 14 blocks the laser light L of the linearly polarized light emitted from the light source unit 12. For example, the shutter 14 can advance and retreat with respect to the optical axis C of the optical member 20 and has a larger area than a beam diameter of the laser light L. The shutter 14 is configured by, for example, a plate where the amount of the laser light L transmitted is small. The plate where the amount of the light transmitted is small is, for example, a metal plate.

The amount of the light transmitted through the shutter 14 is not particularly limited as long as it is the amount of light with which the film 28 to be exposed is not exposed. The amount of the light transmitted is preferably small and most preferably zero.

Although not shown in the drawing, the shutter 14 includes an opening and closing portion that advances and retreats the shutter 14 with respect to the optical axis C. The opening and closing portion is controlled by the controller 26. The shutter 14 is advanced and retreated with respect to the optical axis C by the opening and closing portion driven by the controller 26. The opening and closing portion is not particularly limited, and examples of the opening and closing portion include a portion that rotates the shutter 14 to advance or retreat the shutter 14 and a portion that moves the shutter 14 in one direction with respect to the optical axis C to advance or retreat the shutter 14.

In a state where the shutter 14 is retreated from the optical axis C, a state where the laser light L can be incident into the optical member 20, that is, a state where the film 28 can be exposed is established. On the other hand, in a state where the shutter 14 is advanced into the optical axis C, the laser light L is blocked, the amount of the light transmitted through the optical member 20 is small, and a state where the film 28 cannot be exposed is established.

Before starting the exposure of the film 28, the shutter 14 enter a state where the shutter 14 advances into the optical axis C to block the laser light L. In a state where the exposure of the film 28 starts, the shutter 14 enters a state where the shutter 14 retreats from the optical axis C such that the film can be exposed to the laser light L. After the exposure of the film 28 is completed, the shutter 14 enters a state where the shutter 14 advances into the optical axis C to block the laser light L.

The rotating unit 16 rotates the λ/2 plate 18 around the optical axis C as the rotation axis, and rotates a polarization direction of the linearly polarized light. The λ/2 plate 18 has an action of rotating the polarization direction of the linearly polarized light.

The rotating unit 16 includes, for example, a rotating mount that holds and rotates the λ/2 plate 18, a motor that rotates the rotating mount around the optical axis C as the rotation axis, and a detection unit that detects the rotation amount of the motor. Rotation information such as the rotation amount, the rotation position, and the rotation speed of the λ/2 plate 18 is obtained by the detection unit. The detection unit includes, for example, a rotary encoder. The rotation amount of the motor of the rotating unit 16 is controlled by the controller 26 based on the rotation information of the λ/2 plate 18 obtained by the detection unit. In addition, the rotation speed of the motor of the rotating unit 16 is also controlled by the controller 26.

The optical member 20 focuses the linearly polarized light transmitted through the rotating unit 16 in a ring shape. The optical member 20 is called, for example, an axicon lens.

The laser light L of linearly polarized light transmitted through the optical member 20 spreads in a conical shape around the optical axis C as the central axis, and a portion corresponding to the bottom surface of the cone is circular. Therefore, the laser light L is focused in a ring shape. As described above, the laser light L of linearly polarized light spreads in a conical shape around the optical axis C as the central axis, and thus is focused in a circular shape on a plane perpendicular to the optical axis C.

The optical member 20 is not limited to the axicon lens, and an axicon mirror can also be used. The optical member 20 will be described below.

The stage 22 supports the film 28 including the compound having a photo-aligned group.

A support 27 is disposed on a surface 22a of the stage 22, and the above-described film 28 is formed on a surface 27a of the support 27. The support 27 and the film 28 including the compound having a photo-aligned group will be described below. The surface 22a of the stage 22 is a plane, and the support 27 is disposed such that the optical axis C is a line perpendicular to the plane. Accordingly, the optical axis C is also basically a line perpendicular to a surface 28a of the film 28.

The stage 22 is provided in the moving unit 24.

The moving unit 24 moves the stage 22 in a direction tilted with respect to the optical axis C (optical axis direction C_{L}) of the optical member 20. As a result, the exposure device 10 relatively moves the optical member 20 and the film 28 in the direction tilted with respect to the optical axis C of the optical member 20.

In FIG. 1, it is assumed that a direction parallel to the optical axis C of the optical member 20 is an x direction, a direction orthogonal to the same plane as that of the x direction is a y direction, and a direction orthogonal to an x-y plane, that is, the paper plane is a z direction. For example, the x-y plane is a horizontal plane, and the z direction is the vertical direction.

Accordingly, the direction tilted with respect to the optical axis C of the optical member is a direction including both components of the x direction and the y direction, that is, a so-called an x-y direction.

In the exposure device 10, the optical axis of the light source unit 12, that is, an optical axis of the laser light L (linearly polarized light) emitted from the light source unit 12, the optical axis C of the optical member 20, and a normal line of the film 28 match with each other, all of which are in the x direction.

In the moving unit 24, for example, a motor (not shown) and a movement amount detection unit (not shown) that detects the movement amount of the stage 22 are provided.

The controller 26 obtains position information of the stage 22 from the movement amount of the stage 22 detected by the movement amount detection unit, and controls the movement amount of the stage 22. In addition, the movement speed of the stage 22 is controlled by the controller 26.

The moving unit 24 is not limited to moving the stage 22 in the x-y direction tilted with respect to the optical axis C. That is, the moving unit 24 may also be configured to be capable of moving the stage 22 in one or more directions among the x direction, the y direction, and the z direction as necessary.

That is, the moving unit 24 may also be configured to move the stage 22 in the three directions orthogonal to each other. As a result, the positioning of the film 28 with respect to the linearly polarized light is facilitated.

As the stage 22 and the moving unit 24, for example, various moving stages that are used in a semiconductor manufacturing device can be used.

FIG. 2 is a schematic diagram showing an example of the optical member of the exposure device according to the embodiment of the present invention.

The optical member 20 includes a conical surface 21b having a vertex 21a passing through the optical axis C as shown in FIG. 2. The surface of the conical surface 21b is an emission surface 20a of the optical member 20. A back surface 20b opposite to the conical surface 21b is a plane where the optical axis C is a vertical line. The back surface 20b is an incident surface of the laser light L of linearly polarized light.

In the optical member 20, in a case where the incident laser light L transmits through the conical surface 21b having the vertex 21a, the laser light L of linearly polarized light spreads in a conical shape around the optical axis C as the central axis, and a portion corresponding to the bottom surface of the cone is circular. Therefore, the light Lr having a circular ring shape is focused. The Light Lr maintains the constant width wr.

The light Lr having a circular ring shape is linearly polarized light P₀. Therefore, the surface 28a of the film 28 is irradiated with the linearly polarized light.

In the following description, “circular ring shape” will also be referred to as “annular shape”.

As described above, the laser light L transmitted through the optical member 20 spreads in a conical shape around the optical axis C as the central axis. Therefore, by moving the stage 22 in the optical axis direction C_{L} and changing a distance DL in the optical axis direction C_{L} between the vertex 21a of the optical member 20 and the surface 22a of the stage 22, the diameter of a circle of the bottom surface of the cone changes. Using this configuration, the diameter of the annular light Lr with which the surface 28a of the film 28 is irradiated can be changed.

As a result, using the annular light Lr, the surface 28a of the film 28 can be exposed to a pattern concentrically having the annular exposure patterns Pr around the optical axis C as shown in a schematic diagram of FIG. 3.

As a result, due to the rotation of the λ/2 plate 18, the polarization direction of the linearly polarized light can change depending on the exposure patterns Pr. That is, one exposure pattern Pr is an annular exposure pattern that is exposed by the linearly polarized light facing the same direction.

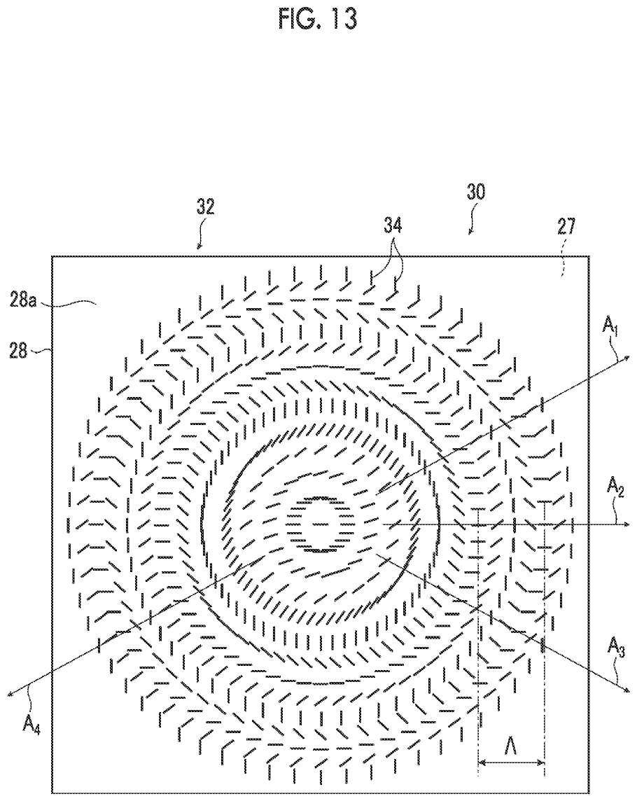

In addition, in the concentric pattern shown in FIG. 3 that is formed by allowing the moving unit 24 to move the stage 22 and allowing the rotating unit 16 to rotate the λ/2 plate 18, the plurality of annular exposure patterns Pr having different orientations of linearly polarized light and different diameters are concentrically formed as in an alignment pattern shown in FIG. 13 below. This concentric exposure pattern is also a pattern where the exposure pattern that is formed by linearly polarized light continuously rotating toward one linear direction is radially formed as in the alignment pattern shown in FIG. 13 below.

Here, as described above, in the exposure device 10 according to the present invention, the moving unit 24 moves the stage 22 that supports the film 28 (support 27) in the direction tilted with respect to the optical axis C of the optical member 20, that is, the x-y direction instead of the optical axis direction C_{L} (x direction) of the optical member 20.

Accordingly, regarding the annular light Lr incident into the surface 28a of the film 28, the diameter changes, and the center of the light Lr on the surface 28a of the film 28, that is, the position of the optical axis of the optical member 20 on the surface 28a of the film 28 is present at the same position in the z direction and moves in the y direction.

As a result, in this aspect, the exposure pattern (alignment pattern) formed in the film 28 is not the concentric exposure pattern shown in FIG. 3 but a pattern that is one-axis symmetrical with respect to the y direction as the symmetrical axis where, as shown in a schematic diagram of FIG. 4, a plurality of annular exposure patterns Pr having different diameters are formed such that the centers match with each other in the z direction and move in the y direction and larger rings sequentially encompass smaller rings.

In addition, in the exposure device 10, the exposure of the film 28 is performed while moving the film 28 in the x-y direction and rotating the λ/2 plate 18. As a result, in each of the annular exposure patterns Pr, the orientation of the linearly polarized light of the light Lr used for the exposure can be rotated.

In the annular exposure patterns Pr, the orientation of the linearly polarized light rotates clockwise from the inner side toward the outer side, for example, the linearly polarized light in the exposure pattern Pr on the innermost side rotates in the direction of 0 o'clock to 6 o'clock, the linearly polarized light in the exposure pattern Pr on the outer side thereof rotates in the direction of 1 o'clock to 7 o'clock, and the linearly polarized light in the exposure pattern Pr on the outer side thereof rotates in the direction of 2 o'clock to 8 o'clock.

As a result, the exposure pattern shown in FIG. 4 is the exposure pattern (alignment pattern) where, as shown in FIG. 13 below, the plurality of annular exposure patterns Pr having different orientations of linearly polarized light and different diameters are radially formed by linearly polarized light continuously rotating toward one linear direction such that the centers thereof match with each other in the z direction and move in the y direction and larger annuli encompass smaller annuli.

As described above, in the exposure device 10 according to the present invention, the linearly polarized light is focused in a ring shape by the optical member 20, and the film 28 is exposed by relatively moving the film 28 and the optical member 20 to change the distance between the film 28 including the compound having a photo-aligned group and the optical member 20.

Therefore, as described in JP2015-532468A, the shape accuracy of the exposure pattern is higher as compared to a case where the circular pattern is formed by moving the stage in two dimensions while rotating linearly polarized light such that the incidence position of the spot into the exposed member (polarization-sensitive exposure medium) moves. As a result, in the exposure device 10, for example, a photo-alignment film having a high-accuracy alignment pattern can be formed.

In addition, the optical element that includes the alignment film having the above-described concentric exposure pattern (alignment pattern) can be used as, for example, a liquid crystal lens (liquid crystal diffractive lens) to be incorporated into a backlight of a liquid crystal display device or a head-mounted display (HMD) such as or augmented reality (AR) glasses that display a virtual image and various information or the like to be superimposed on a scene that is actually being seen or VR (virtual reality) goggles that display an artificially-created virtual space as real.

In the liquid crystal lens for these uses, for example, a lens where the diffraction angle varies in the left-right direction instead of concentrically changing such that the ways that the orientation of light changes vary is also assumed. In this case, it is necessary to draw a plurality of annular or elliptic annular exposure patterns Pr having different center positions instead of being concentric.

On the other hand, in the exposure device 10, the film is exposed by relatively moving the film 28 and the optical member 20 in the x-y direction tilted with respect to the optical axis direction C_{L} of the optical member 20. Therefore, the film 28 can be exposed to the pattern where larger circles encompass smaller circles, for example, at positions shifted in the y direction instead of the concentric pattern.

Regarding the above-described point, the same can also be applied to an exposure method and an exposure device according to a second aspect of the present invention and an exposure method and an exposure device according to a third aspect described below.

In the example shown in the drawing, in a state where a main surface of the film 28 is orthogonal to the optical axis C of the optical member 20, the moving unit 24 moves the stage 22, that is, the film 28 in the x-y direction, that is, in the direction tilted with respect to the optical axis C. That is, in the exposure device 10 of the example shown in the drawing, the moving unit 24 moves the film 28 in the x-y direction while maintaining a normal direction of the film 28 and the optical axis C of the optical member 20 in parallel.

However, the present invention is not limited to this configuration.

The main surface is the maximum surfaces of the film (a sheet-shaped material, a plate-shaped material, a film, or a layer), and is typically both surfaces of the film in the thickness direction. In addition, the normal direction is a direction orthogonal to the main surface, and is typically the thickness direction of the film.

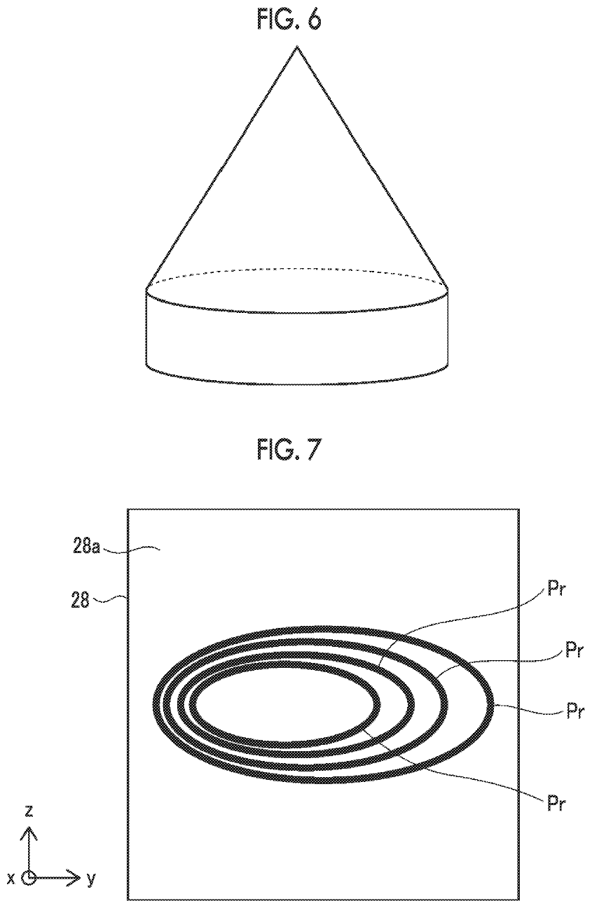

For example, in the first aspect of the present invention, in a state where an angle is formed between the normal line of the film 28 and the optical axis C of the optical member 20, while allowing the stage 22 to support the film 28 and maintaining the angle between the normal line of the film 28 and the optical axis C of the optical member 20, the moving unit 24 may move the film 28 in the x-y direction. As a result, the exposure pattern Pr to which the film 28 is exposed can have an elliptical (oval) ring shape as shown in FIG. 7 below instead of being annular.

In addition, the moving unit 24 may move the film 28 in the x-y direction while changing the angle between the normal line of the film 28 and the optical axis C of the optical member 20. As a result, elliptical exposure patterns Pr having different shapes can be formed.

Here, in the present invention, from the viewpoints of the stability of the exposure pattern to be formed, a reduction in exposure time obtained by performing exposure with lines instead of points, and the like, it is preferable that the moving unit 24 moves the film 28 in the x-y direction while maintaining the angle between the normal line of the film 28 and the optical axis C of the optical member 20, and it is preferable that the moving unit 24 moves the film 28 in the x-y direction while maintaining the normal line of the film 28 and the optical axis C of the optical member 20 in parallel as in the example shown in the drawing.

In the first aspect of the present invention, the angle α between the movement direction of the film 28 by the moving unit 24, that is, the x-y direction and the optical axis C of the optical member 20 is not limited.

Here, in a case where the axicon lens is used as the optical member 20, it is preferable that the angle α between the movement direction of the film 28 by the moving unit 24, that is, the x-y direction and the optical axis C of the axicon lens satisfies

$$α < {sin}^{- 1} ( n \cdot sin θ ) - θ .$$

In this expression, θ represents an angle between a bottom surface and a generatrix (conical surface 21b) of a cone (elliptic cone) configuring the axicon lens, and n represents a refractive index of a material for forming the axicon lens.

In a case where an axicon mirror is used as the optical member 20 and an angle between a bottom surface and a generatrix of a cone (recessed portion) configuring the axicon mirror is represented by θ, it is preferable that the angle α between the movement direction of the film 28 by the moving unit 24, that is, the x-y direction and the optical axis C of the axicon mirror satisfies

$$α < 2 θ .$$

With the above-described configuration, at least a part of the smaller annular exposure pattern Pr can be prevented from being positioned outside the larger annular exposure pattern Pr, and the pattern where the plurality of ring-shaped exposure patterns Pr having different diameters are formed such that the centers move in the y direction and larger circular rings sequentially encompass smaller circular rings can be stably formed.

The angle α between the movement direction of the film 28 by the moving unit 24 and the optical axis C of the axicon lens satisfies more preferably “1.2α<sin⁻¹(n·sin θ)−θ” and still more preferably “1.5α<sin⁻¹(n·sin θ)−θ”.

Likewise, in a case where the axicon mirror is used as the optical member 20, it is more preferable that “1.2α<2θ” is satisfied, and it is still more preferable that “1.5α<2θ” is satisfied.

Regarding this angle α, the same can also be applied to a configuration where the stage 22 is fixed and the optical member 20 moves in the direction tilted with respect to the optical axis C of the optical member 20.

In the exposure device 10, for example, while continuously rotating the rotating unit 16 and rotating the λ/2 plate 18, the rotation speed of the polarization direction of the linearly polarized light can be continuously changed.

In addition, in the exposure device 10, for example, while allowing the moving unit 24 to continuously move the stage 22, the relative movement speed of the film 28 and the optical member 20 can be continuously changed.

Here, continuously changing represents that the relative movement speed changes without entering a state where the change is stopped or the amount of change does not change from the start of change to the end of change. Therefore, in a case where the above-described rotation speed is continuously changed, the rotation speed is not zero or a constant speed.

Therefore, in a case where the above-described movement speed is continuously changed, the movement speed is not zero or a constant speed.

The present invention is not limited to the configuration where the film 28 is exposed by continuously rotating the rotating unit 16 or allowing the moving unit 24 to continuously move the stage 22.

That is, in the exposure device 10, the film 28 may be exposed by rotating the rotating unit 16 stepwise or moving the stage 22 stepwise without being continuous depending on targets to be exposed. For example, an operation in which the film 28 is exposed by allowing the rotating unit 16 to stop the rotation of the λ/2 plate 18 and allowing the moving unit 24 to stop the movement of the stage 22 and subsequently the film 28 is exposed after slightly rotating the λ/2 plate 18 and allowing the moving unit 24 to slightly move the stage 22 may be exposed.

In addition, in the exposure device 10, for example, the rotating unit 16 and the moving unit 24 can be driven in conjunction with each other by the controller 26.

For example, the rotation speed of the rotating unit 16 may be set to a constant speed, and the movement speed of the stage 22, that is, the film 28 may be set to be faster or slower.

For example, in a case where the pitch (interval) of the exposure patterns Pr decreases from the inner side toward the outer side, in a case where the moving unit 24 is driven such that the distance DL increases, that is, the stage 22 is further spaced from the optical member 20 and the rotation speed of the rotating unit 16 is set to a constant speed, the movement speed of the stage 22 may be set to be slower depending on the desired pitch of the exposure patterns Pr.

Conversely, in a case where the moving unit 24 is driven such that the distance DL decreases, that is, the stage 22 approaches the optical member 20 and the rotation speed of the rotating unit 16 is set to a constant speed, the movement speed of the stage 22 may be set to be faster depending on the desired pitch of the exposure patterns Pr.

In addition, the movement speed of the moving unit 24 can also be set to a constant speed, and the rotation speed of the rotating unit 16 can also be set to be faster or slower.

For example, in a case where the pitch of the exposure patterns Pr decreases from the inner side toward the outer side, in a case where the moving unit 24 is driven such that the distance DL increases, that is, the stage 22 is further spaced from the optical member 20 and the movement speed of the stage 22 is set to a constant speed, the rotation speed of the rotating unit 16 may be set to be faster depending on the desired pitch of the exposure patterns Pr.

Conversely, in a case where the moving unit 24 is driven such that the distance DL decreases, that is, the stage 22 approaches the optical member 20 and the movement speed of the stage 22 is set to a constant speed, the rotation speed of the rotating unit 16 may be set to be slower depending on the desired pitch of the exposure patterns Pr.

In addition, for example, the rotation speed of the rotating unit 16 and the movement speed of the moving unit 24 can also be changed independently of each other. In addition, both of the rotation speed of the rotating unit 16 and the movement speed of the moving unit 24 may be changed to expose the film 28 instead of setting one of the rotation speed or the movement speed to a constant speed.

In the present invention, the interval of the annular and elliptic annular (described below) exposure patterns Pr may be regular, the interval of the exposure patterns Pr may be narrowed from the center toward the outer side, or the interval of the exposure patterns Pr may be widened from the center toward the outer side. The interval of the exposure patterns Pr is not particularly limited and can be appropriately selected depending on targets to be manufactured.

As described above, the interval of the exposure patterns Pr can be adjusted by controlling the rotation speed of the rotating unit 16 and/or the movement speed of the moving unit 24.

In the first aspect of the exposure method according to the present invention, the optical member 20 and the film 28 are relatively moved in the direction having an angle with respect to the optical axis C of the optical member 20. That is, in the present invention, as long as the interval between the optical member 20 and the film 28 can be changed, the film 28 may be moved, the optical member 20 may be moved, or both of the film 28 and the optical member 20 may be moved.

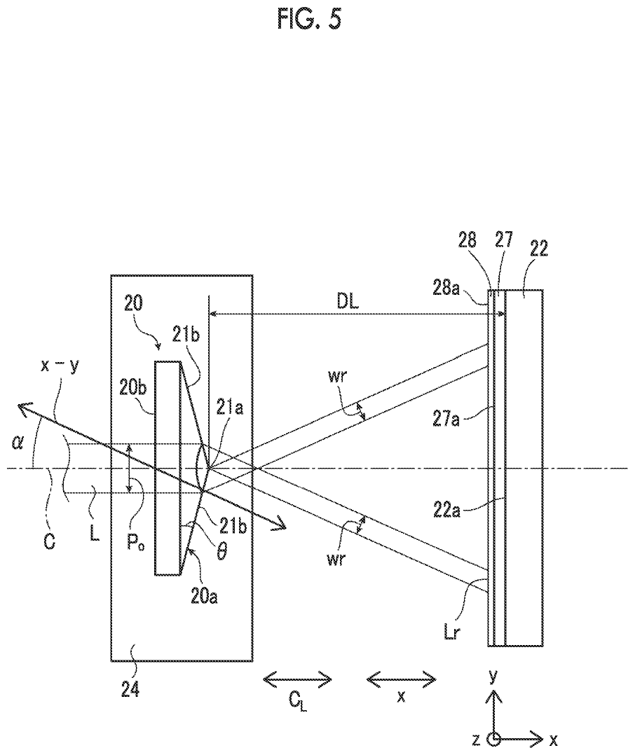

Accordingly, the exposure device 10 shown in FIG. 1 has the configuration in which the optical member 20 is fixed and the stage 22 that supports the film 28 is moved. However, the present invention is not limited to this configuration. Accordingly, the exposure device that implements the exposure method according to the present invention may have a configuration in which, as in a schematic diagram of FIG. 5, the stage 22 is fixed and the optical member 20 moves in the direction having an angle with respect to the optical axis C of the optical member 20, that is, in the x-y direction.

Alternatively, both of the stage 22 and the optical member 20 may be moved in the direction having an angle with respect to the optical axis C of the optical member 20.

In this case, the moving unit 24 is provided in the optical member 20, and the moving unit 24 moves the optical member 20 in the x-y direction tilted with respect to the optical axis C. In consideration of error occurring in the optical system, a positional relationship between the optical member 20 and another optical element such as the optical path length, and the like, in the configuration in which the optical member 20 is moved, it is preferable that not only the optical member 20 but also the optical system including the light source unit 12, the light source portion 13, the shutter 14, the rotating unit 16, the λ/2 plate 18, and the optical member 20 and, in a case where the optical element 19 is provided, further including the optical element 19 are integrally placed on the moving unit 24 and moved.

However, in consideration of error occurring in the optical system, a load on the relative movement of the optical member 20 and the film 28, and the like, it is preferable that, as shown in FIG. 2, the optical member 20 (optical system) is fixed and the moving unit 24 moves the stage 22 (film 28).

In addition, in the exposure device 10 of the example shown in the drawing, as the optical member 20, the conical axicon lens (axicon mirror) of which a cross section in a direction orthogonal to the central axis (rotation axis) is circular is used. However, the present invention is not limited to this configuration.

That is, in the present invention, as the optical member 20, an elliptic conical axicon lens (axicon mirror) of which a cross section in a direction orthogonal to the central axis (rotation axis) is elliptical as shown in a schematic diagram of FIG. 6 may also be used.

By using the elliptic conical axicon lens, the exposure patterns Pr having an elliptical ring shape can be formed as shown in a schematic diagram of FIG. 7.

### (Second Aspect)

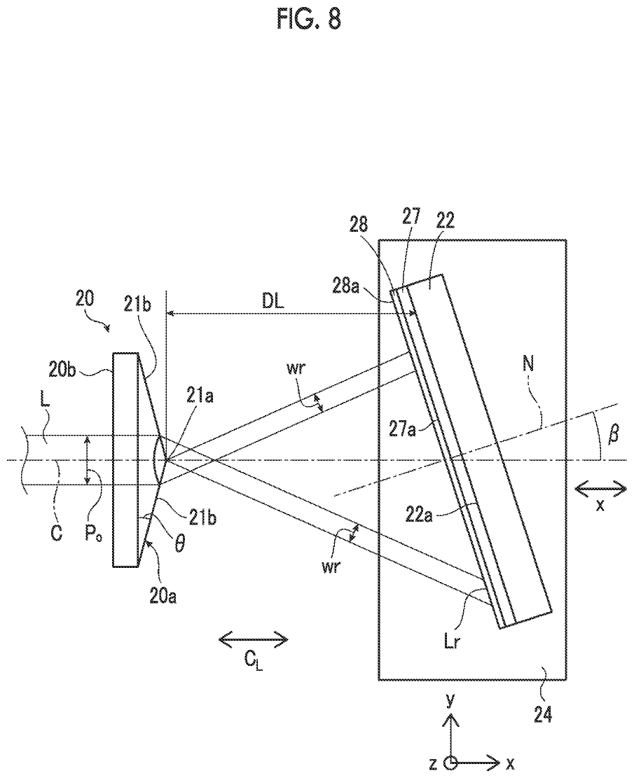

FIG. 8 is a schematic diagram showing an example of a second aspect of the exposure device according to the present invention that implements a second aspect of the exposure method according to the present invention.

In the following description, the second aspect of the exposure method according to the present invention and the second aspect of the exposure device according to the present invention will be collectively referred to as the second aspect of the present invention.

As in the exposure device 10 according to the first aspect shown in FIG. 1, this exposure device is also a device for focusing linearly polarized light in a ring shape with the optical member 20 and exposing the film 28 including the compound having a photo-aligned group.

Basically, the exposure device shown in FIG. 8 is configured by the same members as those of the exposure device 10 according to the first aspect shown in FIG. 1.

That is, as in the exposure device 10 shown in FIG. 1, the exposure device shown in FIG. 8 also includes the light source unit 12 (light source portion 13), the shutter 14, the rotating unit 16, the λ/2 plate 18, the optical member 20, the stage 22, the moving unit 24, and the controller 26. The light source unit 12, the shutter 14, the rotating unit 16, the λ/2 plate 18, the optical member 20, and the stage 22 are disposed in this order along the optical axis C of the optical member 20.

In addition, the operations of the light source unit 12, the shutter 14, the rotating unit 16, and the moving unit 24 are controlled by the controller 26.

Further, the film 28 is formed on the support 27, and the stage 22 supports the support 27 to support the film 28.

Here, the second aspect of the present invention shown in FIG. 8 has the same configuration as the exposure device 10 shown in FIG. 1, except that the stage 22 supports the film 28 in a state where a normal line N of the film 28 including the compound having a photo-aligned group is tilted with respect to the optical axis C of the optical member 20, and the moving unit 24 moves the stage 22, that is, the film 28 in the x direction, that is, the optical axis direction C_{L} of the optical member 20.

Therefore, in the exposure device shown in FIG. 8, only the vicinity of the optical member 20 and the film 28 is shown to simplify the drawing.

In the exposure device shown in FIG. 8, the optical axis of the light source unit 12, that is, the optical axis of the laser light (linearly polarized light) emitted from the light source unit 12 and the optical axis of the optical member 20 match with each other in the x direction, but the normal line N of the film 28 is tilted with respect to both of the optical axes, that is, the x direction.

The x direction, the y direction, and the z direction are the same as those of the above-described first aspect.

In the exposure device shown in FIG. 8, as described above, the film 28 is supported in a state where the normal line N of the film 28 is tilted at an angle β with respect to the optical axis C of the optical member 20 instead of the configuration where the stage 22 supports the film 28 while maintaining the optical axis C of the optical member 20 and the normal line of the film 28 in parallel as in the exposure device 10 shown in FIG. 1.

Accordingly, the optical path length of the light Lr that is focused by the optical member 20 and is incident into the film 28 varies depending on positions in the y direction on the surface 28a of the film 28. In the example shown in the drawing, the optical path length of the light Lr gradually increases from the upper side toward the lower side of FIG. 8 in the y direction.

As described above, the exposure patterns Pr formed by the light Lr that is focused by the optical member 20, that is, the axicon lens increases as the distance DL in the optical axis direction C_{L} between the vertex 21a of the optical member 20 and the surface 22a of the stage 22, that is, the optical path length increases.

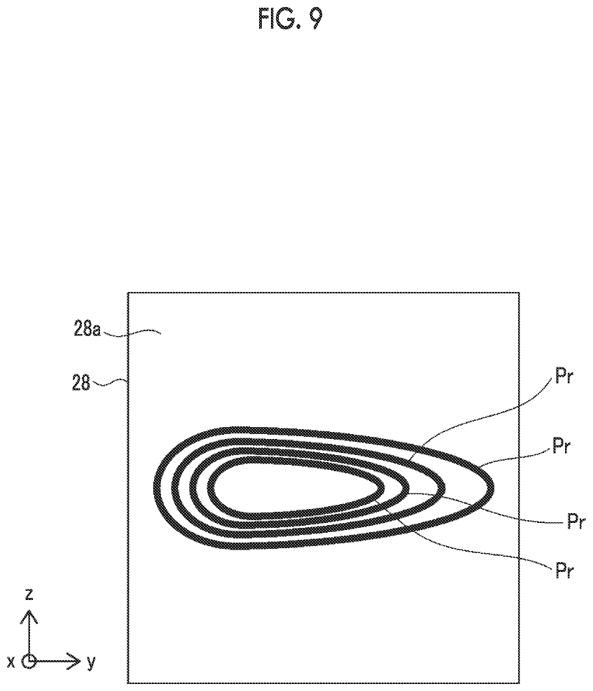

Therefore, the light Lr that is focused by the optical member 20, that is, the axicon lens and is incident into the film 28 has an elliptical ring shape where the minor axis gradually decreases toward one major axis direction. As a result, the film 28 is exposed to the elliptical ring-shaped exposure patterns Pr that are one-axis symmetrical with respect to the y direction as the symmetrical axis where the minor axis gradually decreases toward one major axis direction as shown in a schematic diagram of FIG. 9.

In the following description, “the elliptical ring shape where the minor axis gradually decreases toward one major axis direction” will also be referred to as “deformed elliptic annular shape” for convenience of the description.

In addition, as in the example shown in FIG. 1, the size of the exposure pattern Pr having the deformed elliptic annular shape changes by changing the distance DL in the optical axis direction C_{L} between the vertex 21a of the optical member 20 and the surface 22a of the stage 22. Specifically, the size of the exposure pattern Pr having the deformed elliptic annular shape decreases by decreasing the distance DL, and the size of the exposure pattern Pr having the deformed elliptic annular shape increases by increasing the distance DL.

Accordingly, by allowing the moving unit 24 to move the stage 22 in the optical axis direction C_{L} of the optical member 20, that is, in the x direction such that the film 28 is spaced from the optical member 20 or approaches the optical member 20, an exposure pattern that is one-axis symmetrical with respect to the y direction as the symmetrical axis where, as shown in FIG. 9, the centers in the z direction match with each other and larger exposure patterns Pr having the deformed elliptic annular shape sequentially encompass smaller exposure patterns Pr having the deformed elliptic annular shape can be formed.

In the example shown in FIG. 8, in a state where the angle is provided between the normal line N of the film 28 and the optical axis C of the optical member 20, while allowing the stage 22 to support the film 28 and maintaining the angle β between the normal line N of the film 28 and the optical axis C of the optical member 20, the moving unit 24 moves the film 28 in the x direction.

However, the second aspect of the present invention is not limited to this configuration.

For example, the moving unit 24 may move the film 28 in the x direction while changing the angle between the normal line N of the film 28 and the optical axis C of the optical member 20. As a result, elliptical exposure patterns Pr having different shapes can be formed.

However, in the present invention, from the viewpoints of the stability of the exposure pattern to be formed, a reduction in exposure time obtained by performing exposure with lines instead of points, and the like, it is preferable that the moving unit 24 moves the film 28 in the x direction while maintaining the angle β between the normal line N of the film 28 and the optical axis C of the optical member 20.

In the second aspect of the present invention, the angle β between the normal line N of the film 28 and the optical axis C of the optical member 20 is not limited.

Here, in a case where the axicon lens is used as the optical member 20, it is preferable that the angle β between the normal line N of the film 28 and the optical axis C of the axicon lens satisfies

$$β < 90 - {sin}^{- 1} ( n \cdot sin θ ) + θ .$$

In this expression, θ represents an angle between a bottom surface and a generatrix (conical surface 21b) of a cone (elliptic cone) configuring the axicon lens, and n represents a refractive index of a material for forming the axicon lens.

With the above-described configuration, at least a part of the smaller exposure pattern Pr having the deformed elliptical shape can be prevented from being positioned outside the exposure pattern Pr having the deformed elliptical shape, and the pattern where the larger rings having the deformed elliptical shape sequentially encompass smaller rings having the deformed elliptical shape can be stably formed.

The angle β between the normal line N of the film 28 and the optical axis C of the axicon lens satisfies more preferably “1.2β<90−sin⁻¹(n·sin θ)+θ” and still more preferably “1.5β<90−sin⁻¹(n·sin θ)+θ”.

Likewise, in a case where the axicon mirror is used as the optical member 20, it is more preferable that “1.2β<90-20” is satisfied, and it is still more preferable that “1.5β<90−2θ” is satisfied.

In the second aspect of the present invention, the effects other than the above-described configurations, for example, the rotation and the rotation speed of the optical member such as the axicon lens or the axicon mirror and the λ/2 plate 18, the movement and the movement speed of the stage 22, and the movement of the film 28 and/or the optical member 20 (optical system) are basically the same as those of the first aspect of the present invention described above.

In the second aspect of the present invention, in a case where the film 28 (stage 22) is fixed and the optical member 20 (optical system) moves, the movement direction of the optical member 20 is the optical axis direction C_{L}.

### (Third Aspect)

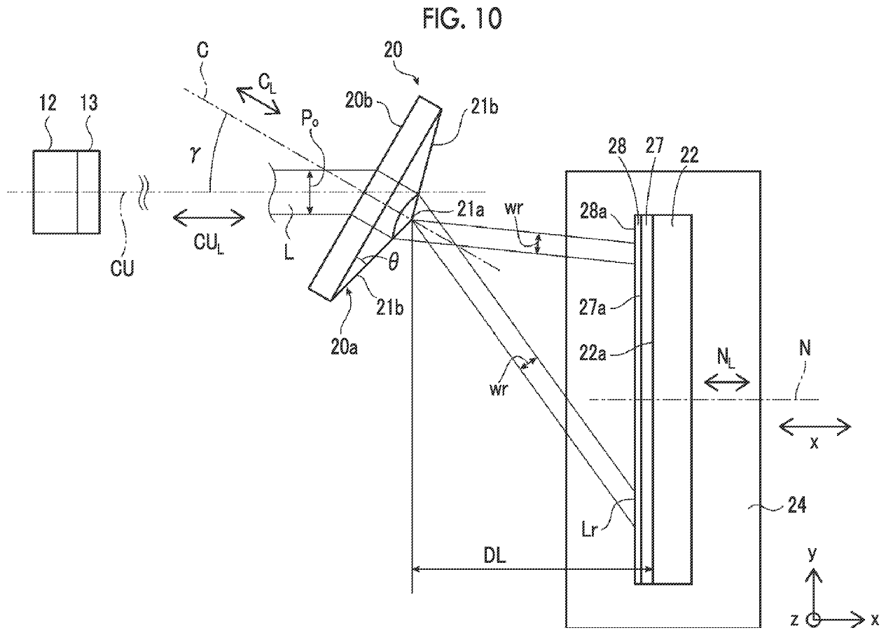

FIG. 10 is a schematic diagram showing an example of a third aspect of the exposure device according to the present invention that implements a third aspect of the exposure method according to the present invention.

In the following description, the third aspect of the exposure method according to the present invention and the third aspect of the exposure device according to the present invention will be collectively referred to as the third aspect of the present invention.

As in the exposure device 10 according to the first aspect shown in FIG. 1, this exposure device is also a device for focusing linearly polarized light in a ring shape with the optical member 20 and exposing the film 28 including the compound having a photo-aligned group.

Basically, the exposure device shown in FIG. 10 is configured by the same members as those of the exposure device 10 according to the first aspect shown in FIG. 1.

That is, as in the exposure device 10 shown in FIG. 1, the exposure device shown in FIG. 10 also includes the light source unit 12 (light source portion 13), the shutter 14, the rotating unit 16, the λ/2 plate 18, the optical member 20, the stage 22, the moving unit 24, and the controller 26. The light source unit 12, the shutter 14, the rotating unit 16, the λ/2 plate 18, the optical member 20, and the stage 22 are disposed in this order along the optical axis C of the optical member 20.

In addition, the operations of the light source unit 12, the shutter 14, the rotating unit 16, and the moving unit 24 are controlled by the controller 26.

Further, the film 28 is formed on the support 27, and the stage 22 supports the support 27 to support the film 28.

Here, in the exposure device shown in FIG. 10, the optical member 20 is disposed such that the optical axis Cis tilted with respect to an optical axis CU of the light source unit 12 (light source portion 13), that is, the optical axis of the laser light L emitted from the light source unit 12. In the first and second aspects of the present invention, the optical axis of the light source unit 12 and the optical axis C of the optical member 20 match with each other in the x direction. However, in the present aspect, only the optical axis CU of the light source unit 12 matches with the x direction.

In addition, the stage 22 that supports the film 28 is disposed on the optical path of the light Lr that is focused by the optical member 20 disposed such that the optical axis C is tilted with respect to the optical axis CU (x direction) of the light source unit 12. The stage 22 moves the film 28 in an optical axis direction CU_{L} of the light source unit 12, that is, the x direction.

That is, in the third aspect of the present invention, the laser light L (linearly polarized light) is incident into the optical member 20 from the direction tilted with respect to the optical axis C of the optical member 20.

The exposure device shown in FIG. 10 has the same configuration as the exposure device 10 shown in FIG. 1, except for the above-described points. Therefore, in FIG. 10, only the vicinity of the optical member 20 and the film 28 to which the light source unit 12 is attached is shown to simplify the drawing.

The x direction, the y direction, and the z direction are the same as those of the above-described first aspect.

In the exposure device shown in FIG. 10, the stage 22 supports the film 28 while maintaining the optical axis CU of the light source unit 12 and the normal line N of the film 28 in parallel. That is, both of the optical axis direction CU_{L} of the light source unit 12 and the normal direction N_{L} of the film 28 are in the x direction.

However, in the exposure device shown in FIG. 10, the optical member 20 is disposed such that the optical axis C is tilted with respect to the optical axis CU of the light source unit 12, that is, the incidence direction of the laser light L.

As described above, the film 28 is disposed on the optical path of the light Lr that is focused by the optical member 20 disposed such that the optical axis C is tilted with respect to the optical axis CU of the light source unit 12. In addition, the film 28 is supported by the stage 22 while maintaining the normal line N and the optical axis CU of the light source unit 12 in parallel.

Accordingly, as in the second aspect of the present invention described above, the optical path length of the light Lr incident into the film 28 varies in the y direction and gradually increases from the upper side toward the lower side in FIG. 10.

As described above, the exposure pattern Pr formed by the light Lr that is focused by the optical member 20, that is, the axicon lens increases as the distance DL in the optical axis direction C_{L} between the vertex 21a of the optical member 20 and the surface 22a of the stage 22, that is, the optical path length increases.

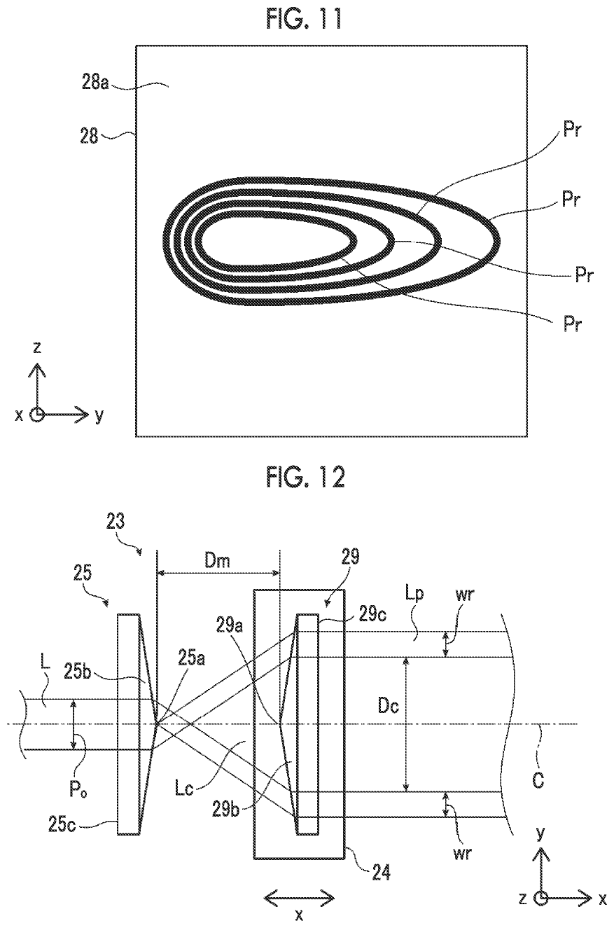

Therefore, the light Lr that is focused by the optical member 20, that is, the axicon lens and is incident into the film 28 has an elliptical shape where the minor axis gradually decreases toward one major axis direction. As a result, as in the above-described second aspect, the film 28 is exposed to the elliptical ring-shaped exposure patterns Pr that are one-axis symmetrical with respect to the y direction as the symmetrical axis where the minor axis gradually decreases toward one major axis direction as shown in a schematic diagram of FIG. 11.

In the following description, as described above, “the elliptical ring shape where the minor axis gradually decreases toward one major axis direction” will also be referred to as “deformed elliptic annular shape” for convenience of the description.

In addition, as in the example shown in FIG. 1, the size of the exposure pattern Pr having the deformed elliptical shape changes by changing the distance DL in the x direction between the vertex 21a of the optical member 20 and the surface 22a of the stage 22. Specifically, the size of the exposure pattern Pr having the deformed elliptic annular shape decreases by decreasing the distance DL, and the size of the exposure pattern Pr having the deformed elliptical shape increases by increasing the distance DL.

Accordingly, by allowing the moving unit 24 to move the stage 22 in the optical axis direction CU_{L} of the optical member 20, that is, in the x direction such that the film 28 is spaced from the optical member 20 or approaches the optical member 20, an exposure pattern that is one-axis symmetrical with respect to the y direction as the symmetrical axis where, as shown in FIG. 11, the centers in the z direction match with each other and larger exposure patterns Pr having the deformed elliptic annular shape sequentially encompass smaller exposure patterns Pr having the deformed elliptic annular shape can be formed.

Here, the exposure patterns Pr having the deformed elliptic annular shape that can be formed in the second aspect of the present invention are positioned near the center portion in the y direction as shown in FIG. 9. On the other hand, the exposure patterns Pr having the deformed elliptic annular shape that can be formed in the third aspect of the present invention are positioned near the left side of the drawing in the y direction as shown in FIG. 11.

That is, in the second aspect of the present invention, the center positions of the exposure patterns Pr having the deformed elliptic annular shape in the y direction match or substantially match with each other, or the movement in the y direction is small. On the other hand, in the third aspect of the present invention, the center positions of the exposure patterns Pr having the deformed elliptic annular shape in the y direction largely move in the y direction, the patterns Pr having the deformed elliptic annular shape are focused on one side in the y direction.

In the example shown in the drawing, in a state where the normal line N of the film 28 and the optical axis CU of the light source unit 12 are maintained in parallel, the moving unit 24 moves the stage 22, that is, the film 28 in the x direction, that is, the optical axis direction CU_{L} of the light source unit 12. That is, in the exposure device 10 of the example shown in the drawing, the moving unit 24 moves the film 28 in the x direction while maintaining the normal line N of the film 28 and the optical axis CU of the light source unit 12 in parallel.

However, the present invention is not limited to this configuration.

For example, in the third aspect of the present invention, in a state where the angle is provided between the normal line N of the film 28 and the optical axis CU of the light source unit 12, while allowing the stage 22 to support the film 28 and maintaining the angle between the normal line N of the film 28 and the optical axis CU of the light source unit 12, the moving unit 24 may move the film 28 in the x direction. As a result, the shapes of the exposure patterns Pr having the deformed elliptic annular shape can be adjusted.

In addition, the moving unit 24 may move the film 28 in the x direction while changing the angle between the normal line N of the film 28 and the optical axis CU of the light source unit 12. As a result, exposure patterns Pr having different deformed elliptic annular shapes can be formed.

However, in the present invention, from the viewpoints of the stability of the exposure pattern to be formed, a reduction in exposure time obtained by performing exposure with lines instead of points, and the like, it is preferable that the moving unit 24 moves the film 28 in the x direction while maintaining the angle between the normal line N of the film 28 and the optical axis CU of the light source unit 12. Further, it is more preferable that the moving unit 24 moves the film 28 in the x direction while maintaining the normal line N of the film 28 and the optical axis CU of the light source unit 12 in parallel.

In the third aspect of the present invention, an angle γ between the optical axis CU of the light source unit 12, that is, an incidence direction of light L into the optical member 20 and the optical axis C of the optical member 20 is not limited.

Here, in a case where the axicon lens is used as the optical member 20, it is preferable that the angle γ between the optical axis CU of the light source unit 12 and the optical axis C of the axicon lens satisfies

$${sin}^{- 1} ( n \cdot sin ( θ + γ ) ) - θ - γ > 0.$$

In this expression, θ represents an angle between a bottom surface and a generatrix (conical surface 21b) of a cone (elliptic cone) configuring the axicon lens, and n represents a refractive index of a material for forming the axicon lens.

In a case where an axicon mirror is used as the optical member 20 and an angle between a bottom surface and a generatrix of a cone (recessed portion) configuring the axicon mirror is represented by θ, it is preferable that the angle γ between the optical axis CU of the light source unit 12 and the optical axis C of the axicon mirror satisfies

$$γ < 2 θ .$$

With the above-described configuration, at least a part of the smaller exposure pattern Pr having the deformed elliptical shape can be prevented from being positioned outside the exposure pattern Pr having the deformed elliptical shape, and the pattern where the larger rings having the deformed elliptical shape sequentially encompass smaller rings having the deformed elliptical shape can be stably formed.

In addition, the angle γ between the optical axis CU of the light source unit 12 and the optical axis C of the axicon lens satisfies more preferably “sin⁻¹(n·sin(θ+1.2γ))−θ−1.2γ>0” and still more preferably “sin⁻¹(n·sin(θ+1.5γ))−θ−1.5γ>0”.

Likewise, in a case where the axicon mirror is used as the optical member 20, it is more preferable that “1.2γ<2θ” is satisfied, and it is still more preferable that “1.5γ<2θ” is satisfied.

In the third aspect of the present invention, the effects other than the above-described configurations, for example, the rotation and the rotation speed of the optical member such as the axicon lens or the axicon mirror and the λ/2 plate 18, the movement and the movement speed of the stage 22, and the movement of the film 28 and/or the movement of the optical member 20 (optical system) are basically the same as those of the first aspect of the present invention described above.

In the third aspect of the present invention, in a case where the film 28 (stage 22) is fixed and the optical member 20 moves, the movement direction of the optical member 20 is the optical axis direction of the light source unit 12, that is, the x direction.

### Another Example of Optical Member

In the second aspect of the present invention and the third aspect of the present invention, the configuration of the optical member 20 is not limited to the example shown in FIG. 2. FIG. 12 is a schematic diagram showing another example of the optical member that can be used in the second aspect of the present invention and the third aspect of the present invention. In FIG. 12, the same components as those of FIGS. 1 and 2 are represented by the same reference numerals, and the detailed description thereof will not be repeated.

As shown in FIG. 12, an optical member 23 includes a first optical element 25 and a second optical element 29. Although not shown in the drawing, the stage 22 is positioned on a back surface 29c side of the second optical element 29 of the optical member 23.

In addition, the moving unit 24 is provided in the second optical element 29, and the moving unit 24 is not provided in the stage 22.

The first optical element 25 and the second optical element 29 have the same configuration as the above-described optical member 20 shown in FIG. 2. The first optical element 25 and the second optical element 29 are disposed such that a vertex 25a and a vertex 29a face each other.

The first optical element 25 includes a conical surface 25b having the vertex 25a passing through the optical axis C. The surface of the conical surface 25b is the emission surface of light. A back surface 25c opposite to the conical surface 25b is a plane where the optical axis C is a vertical line. The back surface 25c is an incident surface of the laser light L of linearly polarized light.

The second optical element 29 includes a conical surface 29b having the vertex 29a passing through the optical axis C. The surface of the conical surface 29b is the incident surface of the ring-shaped light Lr emitted from the first optical element 25. In addition, the back surface 29c opposite to the conical surface 29b is a plane where the optical axis C is a vertical line. The back surface 29c is an emission surface of exposure light Lp.

In the optical member 23, in a case where the incident laser light L incident into the back surface 25c of the first optical element 25 transmits through the conical surface 25b having the vertex 25a, the light L spreads in a conical shape around the optical axis C as the central axis to obtain conical light Lc, and the conical light Lc is incident into the conical surface 29b of the second optical element 29. The conical light Lc is diffracted in parallel to the optical axis C to be cylindrical light on the conical surface 29b of the second optical element 29. The cylindrical light transmits through the second optical element 29 such that cylindrical light of which the circumferential surface is parallel to the optical axis C is emitted from the back surface 29c. Since a portion corresponding to the bottom surface of the cylinder is circular, the ring-shaped light Lr is focused on the surface 28a of the film 28. In the cylindrical light, the width wr of the portion corresponding to the circumferential surface of the cylinder is constant. The cylindrical light emitted from the back surface 29c will be referred to as the exposure light Lp.

Due to the exposure light Lp, the surface 28a of the film 28 is exposed to the ring-shaped light Lr as shown in FIG. 3.

Since the exposure light Lp is cylindrical, even in a case where the distance in the optical axis direction CI between the second optical element 29 and the stage 22 changes, a diameter Dc of the exposure light Lp does not change. That is, the diameter of the ring-shaped light Lr does not change.

By changing a distance Dm in the optical axis direction CI between the vertex 25a of the first optical element 25 and the vertex 29a of the second optical element 29, the position where the conical light Lc is incident into the conical surface 29b of the second optical element 29 changes. As a result, the position of the exposure light Lp emitted from the back surface 29c of the second optical element 29 changes. Therefore, by allowing the moving unit 24 to change the position of the second optical element 29 such that the above-described distance Dm changes, the diameter Dc of the cylindrical exposure light Lp can be changed.

In the configuration of FIG. 12, in a case where the distance Dm decreases, the diameter Dc of the cylindrical exposure light Lp decreases, and in a case where the distance Dm increases, the diameter Dc of the cylindrical exposure light Lp increases. By using this configuration, the concentric exposure patterns Pr shown in FIG. 3 can be formed around the optical axis C (refer to FIG. 4).

The moving unit 24 changing the position in the optical axis direction C_{L} of the second optical element 29 corresponds to changing the distance in the optical axis direction C_{L} of the optical member 23 between the optical member 23 and the stage 22.

The optical member 23 shown in FIG. 12 has the configuration in which the moving unit 24 changes the position of the second optical element 29. The present aspect is not limited to this configuration, and the optical member 23 may have a configuration in which the moving unit 24 changes the position of the first optical element 25. Even in this case, the diameter Dc of the cylindrical exposure light Lp can be changed using the same method as that of allowing the moving unit 24 to change the position of the second optical element 29.

In the above-described exposure device 10, even in a case where the optical member 20 is replaced with the optical member 23 shown in FIG. 4, the exposure patterns Pr as shown in FIG. 3 can be concentrically exposed with high shape accuracy, and a photo-alignment film where the accuracy of an alignment pattern is high can be obtained. Even in the exposure method, as in the exposure device, the concentric exposure patterns Pr can be exposed with high shape accuracy, and a photo-alignment film where the accuracy of an alignment pattern is high can be obtained.

In a case where the laser light L incident into the first optical element 25 is parallel light, by the first optical element 25, the width wr of the ring-shaped light can be made more uniform, the width wr of the exposure light Lp can be made more uniform, and thus the width of the exposure pattern Pr can be made more uniform. Therefore, the exposure can be performed with high accuracy. Therefore, the laser light L incident into the first optical element 25 is preferably parallel light.

### (Exposure Method)

In a case where the film 28 is exposed using the above-described exposure device, exposure conditions such as the intensity of the laser light L emitted from the light source unit 12, the rotation speed of the rotating unit 16, and the movement direction and the movement speed of the stage 22 by the moving unit 24 are predetermined depending on exposure patterns to be formed. In the exposure method according to the present invention, the exposure is performed based on the predetermined exposure conditions.

In a case where the film 28 including the compound having a photo-aligned group is exposed, the film 28 formed on the surface 27a of the support 27 is disposed on the stage 22.

In addition, the shutter 14 is disposed on the optical axis C to enter a state where the light does not reach the stage 22, that is, the surface 28a of the film 28.

Next, the laser light L of linearly polarized light is emitted from the light source portion 13 of the light source unit 12. The shutter 14 is retreated from the optical axis C to enter a state where the light reaches the stage 22, and the rotating unit 16 is rotated to rotate the λ/2 plate 18 such that the polarization direction of the linearly polarized light changes.

At this time, the moving unit 24 moves the stage 22 in a predetermined movement direction at a predetermined movement speed to expose the film 28.

That is, in the first aspect, the stage 22 moves in the x-y direction tilted with respect to the optical axis C of the optical member 20. In the second aspect, in a state where the normal line N of the film 28 is tilted with respect to the optical axis C of the optical member 20, the stage 22 moves in the x direction that matches with the optical axis direction C_{L} of the optical member 20. Further, in the third aspect, in a state where the optical axis C of the optical member 20 is tilted with respect to the optical axis CU of the light source unit 12, that is, the incidence direction of the light, the stage 22 moves in the x direction that matches with the optical axis direction CU_{L} of the light source unit 12.

As a result, while rotating the polarization direction of the linearly polarized light, the film 28 and the optical member 20 are relatively moved to expose the film 28.

After the completion of the exposure step, the shutter 14 is disposed on the optical axis C to enter a state where the light does not reach the surface 28a of the film 28. Next, the support 27 where the film 28 is provided is removed from the stage 22.

In the first aspect of the present invention, the laser light L of linearly polarized light is focused to the annular exposure patterns Pr as shown in FIG. 4 to expose the film 28. On the other hand, in the second and third aspects, the laser light L of linearly polarized light is focused to the exposure patterns Pr having the deformed elliptic annular shape as shown in FIGS. 9 and 11 to expose the film 28.

Due to the movement of the stage 22, the size of the ring-shaped light Lr changes, and the optical axis C (refer to FIG. 2) on the surface 28a of the film 28, that is, the center of the ring-shaped light Lr moves. Alternatively, only the size of the ring-shaped light Lr changes. As a result, as shown in FIGS. 4, 9, and 11, the film 28 is exposed to the pattern that is one-axis symmetrical with respect to the y direction as the symmetrical axis where the plurality of ring-shaped exposure patterns Pr having different diameters are formed such that larger rings sequentially encompass smaller rings.

In addition, the exposure patterns Pr are exposed to linearly polarized light components having different polarization directions, and the orientations of the linearly polarized light in one exposure pattern Pr having the annular or deformed elliptic annular shape are the same.

As described above, in the exposure method according to the present invention, the linearly polarized light is focused in a ring shape by the optical member 20, and the film 28 is exposed by relatively moving the film 28 including the compound having a photo-aligned group and the optical member 20.

Therefore, the shape accuracy of the exposure pattern is higher than that in a case where the circular pattern is formed by moving the stage in two dimensions to change the incidence position of laser light into the exposed member as described in JP2015-532468A. As a result, in the exposure method, a photo-alignment film where the accuracy of an alignment pattern can be obtained.

That is, in the exposure method according to the present invention, in the first aspect, the stage 22 moves in the x-y direction tilted with respect to the optical axis C of the optical member 20. In the second aspect, in a state where the normal line N of the film 28 is tilted with respect to the optical axis C of the optical member 20, the stage 22 moves in the x direction that matches with the optical axis direction of the optical member 20. Further, in the third aspect, in a state where the optical axis C of the optical member 20 is tilted with respect to the optical axis CU of the light source unit 12, that is, the incidence direction of the light, the stage 22 moves in the x direction that matches with the optical axis direction of the light source unit 12.

Therefore, in the exposure method according to the embodiment of the present invention, instead of the concentric pattern shown in FIG. 3, the film 28 can be exposed to the one-axis symmetrical patterns where, as shown in FIGS. 4 and 9, the positions of the rings having a circular shape, a deformed elliptical shape, or the like are shifted and larger rings encompass smaller rings.

Using the above-described exposure device or exposure method, a photo-alignment film can be formed.

Here, the pattern formed on the film 28 by the exposure according to the present invention is not the concentric pattern but the one-axis symmetrical patterns where, as shown in FIGS. 4 and 9, the positions of the rings having a circular shape, a deformed elliptical shape, or the like are moved and larger rings encompass smaller rings.

However, in the following description, in order to easily understand the actions of the alignment pattern and the liquid crystal alignment pattern, the concentric pattern will be described as an example. The same optical effects of an optical element having a liquid crystal alignment pattern are basically the same with the concentric pattern or with the deformed pattern shown in FIGS. 4 and 9.

The photo-alignment film is formed by exposing the film 28 (refer to FIG. 1) including the compound having a photo-aligned group to the circular ring-shaped (annular) linearly polarized light.

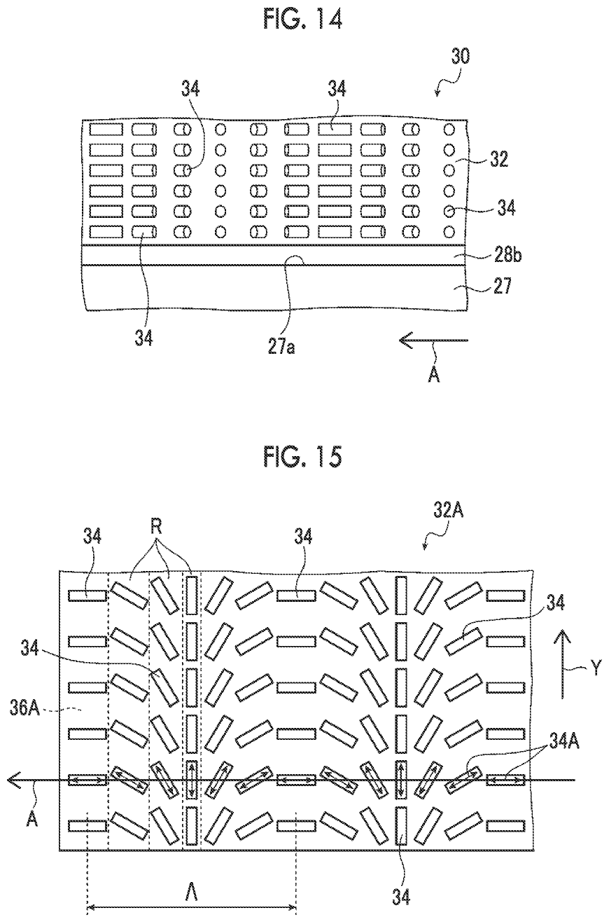

Examples of a method of forming the photo-alignment film include a method of forming a photo-alignment film 28b as the film 28 on the support 27, for example, as schematically shown in FIG. 14.

### (Support)

As the support 27, various sheet-shaped materials (films or plate-shaped materials) can be used as long as they can support the photo-alignment film 28b (film 28) and an optically-anisotropic layer 32 described below.

As the support 27, a transparent support is preferable, and examples thereof include a polyacrylic resin film such as polymethyl methacrylate, a cellulose resin film such as cellulose triacetate, a cycloolefin polymer film (for example, trade name “ARTON”, manufactured by JSR Corporation; or trade name “ZEONOR”, manufactured by Zeon Corporation), polyethylene terephthalate (PET), polycarbonate, and polyvinyl chloride. The support is not limited to a flexible film and may be a non-flexible substrate such as a glass substrate.

### (Photo-Alignment Film)

The film 28 including the compound having a photo-aligned group is formed on the surface 27a of the support 27.

Next, the film 28 is concentrically irradiated with the ring-shaped light of linearly polarized light by the exposure device 10. As a result, the photo-alignment film 28b having the alignment pattern is formed based on the concentric (radial) exposure patterns Pr shown in FIG. 3.

The concentric (radial) exposure patterns Pr shown in FIG. 3 are the same alignment pattern as a pattern radially including the pattern shown in FIG. 13 where a short line (short straight line) changes while continuously rotating toward one direction based on the polarization direction of the linearly polarized light. The photo-alignment film 28b having this alignment pattern can be formed.

Here, in the exposure method, the concentric (radial) exposure patterns Pr can be obtained as shown in FIG. 3. In the exposure patterns Pr, the polarization directions of the linearly polarized light are different from each other. Therefore, in the exposure patterns Pr, as shown in FIG. 13, the short straight line changes while continuously rotating in a plurality of directions from the center toward the outer side, for example, a direction indicated by an arrow A₁, a direction indicated by an arrow A₂, a direction indicated by an arrow A₃, a direction indicated by an arrow A₄, or . . . . In the following description, the short straight line of which the orientation changes while continuously rotating will be referred to as “short line” for convenience of description.

The rotation direction of the short line is the same direction in all of the directions (one direction). In the example shown in the drawing, in all the directions including the direction indicated by the arrow A₁, the direction indicated by the arrow A₂, the direction indicated by the arrow A₃, and the direction indicated by the arrow A₄, the rotation direction of the short line is counterclockwise.

That is, in a case where the arrow A₁ and the arrow A₄ are assumed as one straight line, the rotation direction of the short line is reversed at the center on the straight line. For example, the straight line formed by the arrow A₁ and the arrow A₄ is directed in the right direction (arrow A₁ direction) in the drawing. In this case, the short line initially rotates clockwise from the outer side to the center, the rotation direction is reversed at the center, and then the short line rotates counterclockwise from the center to the outer side.

In addition, in the exposure patterns Pr (refer to FIG. 3), as shown in FIG. 13, in a case where a length over which the orientation of the short line rotates by 180° in the one direction in which the orientation of the short line changes while continuously rotating is set as a single period Λ, the length of the single period Λ gradually decreases from the inner side toward the outer side. The single period Λ will be described below.

(Compound having Photo-Aligned Group)

Preferable examples of the compound having a photo-aligned group that is, the photo-alignment material used in the photo-alignment film 28b that can be used in the present invention include: an azo compound described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, and JP4151746B; an aromatic ester compound described in JP2002-229039A; a maleimide- and/or alkenyl-substituted nadiimide compound having a photo-alignable unit described in JP2002-265541A and JP2002-317013A; a photocrosslinking silane derivative described in JP4205195B and JP4205198B, a photocrosslinking polyimide, a photocrosslinking polyamide, or a photocrosslinking ester described in JP2003-520878A, JP2004-529220A, and JP4162850B; and a photodimerizable compound, in particular, a cinnamate (cinnamic acid) compound, a chalcone compound, or a coumarin compound described in JP1997-118717A (JP-H9-118717A), JP1998-506420A (JP-H10-506420A), JP2003-505561A, WO2010/150748A, JP2013-177561A, and JP2014-12823A.

Among these, an azo compound, a photocrosslinking polyimide, a photocrosslinking polyamide, a photocrosslinking ester, a cinnamate compound, or a chalcone compound is suitably used.

### (Method of Forming Optically-Anisotropic Layer)

Using the above-described exposure device (exposure method), an optically-anisotropic layer can be formed.

The method of forming an optically-anisotropic layer includes applying a composition including a liquid crystal compound to the photo-alignment film 28b and aligning the liquid crystal compound to form an optically-anisotropic layer. In the method of forming an optically-anisotropic layer, the liquid crystal compound may be dried and further optionally cured.

As described above, the photo-alignment film 28b is formed on the support 27. An optical element 30 shown in FIGS. 13 and 14 includes the optically-anisotropic layer 32 that is formed on the photo-alignment film 28b using the composition including the liquid crystal compound.

FIGS. 13 and 14 show an example of the optical element formed using the method of forming an optical element. FIG. 13 is a schematic plan view showing an example of an optical element manufactured using the exposure method according to the embodiment of the present invention. In addition, FIG. 14 is a schematic cross-sectional view showing the example of the optical element manufactured using the exposure method according to the embodiment of the present invention. The plan view is a view in a case where the optical element 30 is seen from a thickness direction (laminating direction of the respective layers (films)).

For example, as described above, the photo-alignment film 28b includes the pattern where the orientation of the short line changes while continuously rotating toward one direction in a radial shape from the inner side toward the outer side.

The optically-anisotropic layer 32 that is formed on the photo-alignment film 28b using a composition including a liquid crystal compound includes a liquid crystal alignment pattern where an orientation of an optical axis derived from a liquid crystal compound 34 changes while continuously rotating toward one direction in a radial shape from the inner side toward the outer side. That is, the liquid crystal alignment pattern in the optically-anisotropic layer 32 shown in FIGS. 13 and 14 is a concentric pattern including the one direction in which the orientation of the optical axis derived from the liquid crystal compound 34 changes while continuously rotating in a concentric shape from the inner side toward the outer side.

In FIGS. 13 to 17, for example, a rod-like liquid crystal compound is used as the liquid crystal compound 34. Therefore, the direction of the optical axis matches with a longitudinal direction of the liquid crystal compound 34.

In the optically-anisotropic layer 32, the orientation of the optical axis of the liquid crystal compound 34 changes while continuously rotating in a plurality of directions from the center toward the outer side of the optically-anisotropic layer 32, for example, a direction indicated by an arrow A₁, a direction indicated by an arrow A₂, a direction indicated by an arrow A₃, a direction indicated by an arrow A₄, or . . . .

Accordingly, in the optically-anisotropic layer 32, the rotation direction of the optical axis of the liquid crystal compound 34 is the same in all the directions (one direction). In the example shown in the drawing, in all the directions including the direction indicated by the arrow A₁, the direction indicated by the arrow A₂, the direction indicated by the arrow A₃, and the direction indicated by the arrow A₄, the rotation direction of the optical axis of the liquid crystal compound 34 is counterclockwise.

That is, in a case where the arrow A₁ and the arrow A₄ are assumed as one straight line, the rotation direction of the optical axis of the liquid crystal compound 34 is reversed at the center of the optically-anisotropic layer 32 on the straight line. For example, the straight line formed by the arrow A₁ and the arrow A₄ is directed in the right direction (arrow A₁ direction) in the drawing. In this case, the optical axis of the liquid crystal compound 34 initially rotates clockwise from the outer side to the center of the optically-anisotropic layer 32, the rotation direction is reversed at the center of the optically-anisotropic layer 32, and then the optical axis of the liquid crystal compound 34 rotates counterclockwise from the center to the outer side of the optically-anisotropic layer 32.

In addition, in the optically-anisotropic layer 32 of the optical element 30, in the liquid crystal alignment pattern, in a case where a length over which the orientation of the optical axis derived from the liquid crystal compound rotates by 180° in the one direction in which the orientation of the optical axis derived from the liquid crystal compound 34 changes while continuously rotating is set as a single period, the length of the single period gradually decreases from the inner side toward the outer side.

In circularly polarized light incident into the optically-anisotropic layer 32 having the above-described liquid crystal alignment pattern, an absolute phase changes depending on individual local regions having different orientations of optical axes of the liquid crystal compound 34. In this case, the amount of change in absolute phase in each of the local regions varies depending on the orientations of the optical axes of the liquid crystal compound 34 into which circularly polarized light is incident.

In the optically-anisotropic layer (optical element 30) having the liquid crystal alignment pattern in which the orientation of the optical axis of the liquid crystal compound 34 changes while continuously rotating in the one direction, a refraction direction of transmitted light depends on the rotation direction of the optical axis of the liquid crystal compound 34. That is, in this liquid crystal alignment pattern, in a case where the rotation direction of the optical axis of the liquid crystal compound 34 is reversed, the refraction direction of transmitted light is also reversed with respect to the one direction in which the optical axis rotates.

In addition, the diffraction angle of the optically-anisotropic layer 32 increases as the single period decreases. That is, the refraction of light of the optically-anisotropic layer 32 increases as the single period decreases.

Accordingly, in the optically-anisotropic layer 32 having the concentric liquid crystal alignment pattern, that is, the liquid crystal alignment pattern in which the optical axis changes while continuously rotating radially, incidence light (light beam) can be diffused or be focused and transmitted depending on the rotation direction of the optical axis of the liquid crystal compound 34 and the turning direction of circularly polarized light to be incident.

The optically-anisotropic layer 32 is formed of a composition including a liquid crystal compound.

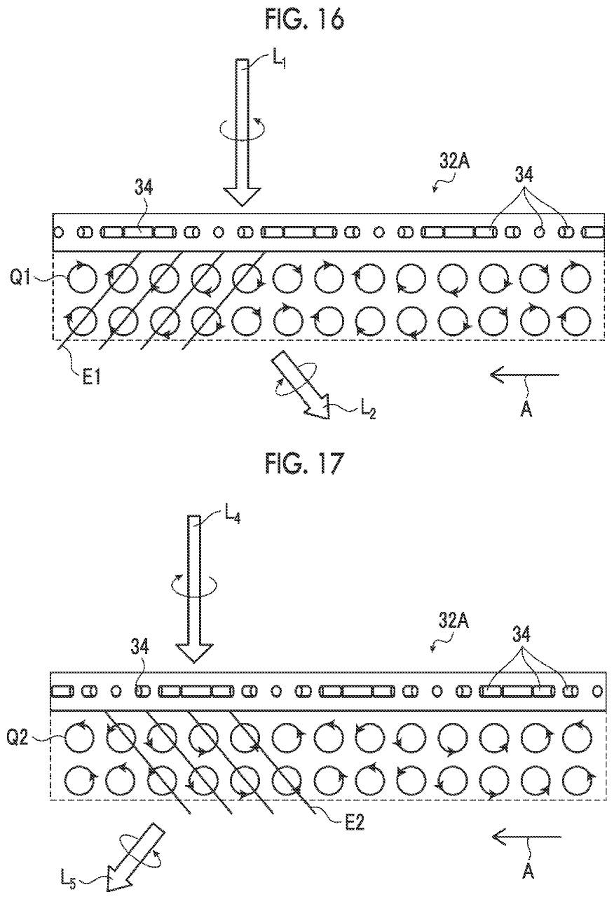

In FIG. 14, in order to simplify the drawing and to clarify the configuration of the optical element 30, only the liquid crystal compound 34 (liquid crystal compound molecules) on the surface of the photo-alignment film 28b in the optically-anisotropic layer 32 is shown. However, as schematically shown in FIG. 14, the optically-anisotropic layer 32 has a structure in which the aligned liquid crystal compounds 34 are laminated as in an optically-anisotropic layer that is formed using a composition including a typical liquid crystal compound. Regarding this point, the same can also be applied to FIGS. 16 and 17 described below.

In a case where an in-plane retardation value (retardation in a plane direction) is set as λ/2, the optically-anisotropic layer 32 has a function of a general λ/2 plate, that is, a function of imparting a retardation of a half wavelength, that is, 180° to two linearly polarized light components in light incident into the optically-anisotropic layer and are orthogonal to each other.

In a plane of the optically-anisotropic layer, the optically-anisotropic layer 32 includes the liquid crystal alignment pattern where the orientation of the optical axis derived from the liquid crystal compound changes while continuously rotating in one direction (for example, directions of the arrow A₁ to the arrow A₄ in FIG. 13) in a radial shape from the inner side toward the outer side.

An optical axis 34A derived from the liquid crystal compound 34 is an axis having the highest refractive index in the liquid crystal compound 34, that is, a so-called slow axis. For example, in a case where the liquid crystal compound 34 is a rod-like liquid crystal compound, the optical axis 34A is along a rod-like major axis direction.

In the following description, the optical axis 34A derived from the liquid crystal compound 34 will also be referred to as “the optical axis 34A of the liquid crystal compound 34” or “the optical axis 34A”.

Hereinafter, the optically-anisotropic layer 32 will be described with reference to an optically-anisotropic layer 32A that includes a liquid crystal alignment pattern where the optical axes 34A change while continuously rotating in one direction indicated by an arrow A as schematically shown in a plan view of FIG. 15.

Even in the liquid crystal alignment pattern shown in FIG. 13 that includes one direction in which the optical axis changes while continuously rotating in a radial shape (concentric shape) from the inner side toward the outer side, the same optical effects as those of the liquid crystal alignment pattern shown in FIG. 15 can be exhibited for the one direction in which the optical axis changes while continuously rotating.

In the optically-anisotropic layer 32A, the liquid crystal compound 34 is two-dimensionally aligned in a plane parallel to the one direction indicated by the arrow A and a Y direction orthogonal to the arrow A direction. In FIGS. 16 and 17 described below, the Y direction is a direction orthogonal to the paper plane.

In the following description, “one direction indicated by the arrow A” will also be simply referred to as “arrow A direction”.

In the optically-anisotropic layer 32 shown in FIG. 13, a circumferential direction of a concentric circle in the concentric liquid crystal alignment pattern corresponds to the Y direction in FIG. 15.

The optically-anisotropic layer 32A has the liquid crystal alignment pattern in which the orientation of the optical axis 34A derived from the liquid crystal compound 34 changes while continuously rotating in the arrow A direction in a plane of the optically-anisotropic layer 32A.

Specifically, “the orientation of the optical axis 34A of the liquid crystal compound 34 changes while continuously rotating in the arrow A direction (the predetermined one direction)” represents that an angle between the optical axis 34A of the liquid crystal compound 34, which is arranged in the arrow A direction, and the arrow A direction varies depending on positions in the arrow A direction, and the angle between the optical axis 34A and the arrow A direction sequentially changes from θ to θ+180° or θ−180° in the arrow A direction.

A difference between the angles of the optical axes 34A of the liquid crystal compound 34 adjacent to each other in the arrow A direction is preferably 45° or less, more preferably 15° or less, and still more preferably less than 15°.

On the other hand, regarding the liquid crystal compound 34 forming the optically-anisotropic layer 32A, the liquid crystal compounds 34 having the same orientation of the optical axes 34A are arranged at regular intervals in the Y direction orthogonal to the arrow A direction, that is, the Y direction orthogonal to the one direction in which the optical axis 34A continuously rotates.

In other words, regarding the liquid crystal compound 34 forming the optically-anisotropic layer 32, in the liquid crystal compounds 34 arranged in the Y direction, angles between the orientations of the optical axes 34A and the arrow A direction are the same.

In the optically-anisotropic layer 32 shown in FIG. 13, a region where the orientations of the optical axes 34A are the same is formed in a ring shape where the centers match with each other.

As in the above-described short line, even in the optically-anisotropic layer 32, in the liquid crystal alignment pattern in which the optical axis 34A continuously rotates in the one direction, a length (distance) over which the optical axis 34A of the liquid crystal compound 34 rotates by 180° is set as a length Λ of the single period in the liquid crystal alignment pattern.

That is, in the optically-anisotropic layer 32A shown in FIG. 15, the length (distance) over which the optical axis 34A of the liquid crystal compound 34 rotates by 180° in the arrow A direction in which the orientation of the optical axis 34A changes while continuously rotating in a plane is set as the single period Λ in the liquid crystal alignment pattern. In other words, the single period Λ in the liquid crystal alignment pattern is defined by the distance between θ and θ+180° that is a range of the angle between the optical axis 34A of the liquid crystal compound 34 and the arrow A direction.

That is, a distance between centers of two liquid crystal compounds 34 in the arrow A direction is the single period Λ the two liquid crystal compounds having the same angle in the arrow A direction. Specifically, as shown in FIG. 15, a distance between centers in the arrow A direction of two liquid crystal compounds 34 in which the arrow A direction and the direction of the optical axis 34A match with each other is the single period Λ.

In the optically-anisotropic layer 32A (optically-anisotropic layer 32), in the liquid crystal alignment pattern of the optically-anisotropic layer, the single period Λ is repeated in the arrow A direction, that is, in the one direction in which the orientation of the optical axis 34A changes while continuously rotating.

In the optical element 30 having the liquid crystal alignment pattern where the optical axis 34A continuously rotates in a radial shape (concentric shape), the single period Λ in the optically-anisotropic layer 32 gradually decreases from the inner side (center) toward the outer side.

As described above, in the liquid crystal compounds arranged in the Y direction in the optically-anisotropic layer 32A, the angles between the optical axes 34A and the arrow A direction (the one direction in which the orientation of the optical axis of the liquid crystal compound 34 rotates) are the same. Regions where the liquid crystal compounds 34 in which the angles between the optical axes 34A and the arrow A direction are the same are disposed in the Y direction will be referred to as “regions R”.

In this case, it is preferable that an in-plane retardation (Re) value of each of the regions R is a half wavelength, that is, λ/2. The in-plane retardation is calculated from the product of a difference Δn in refractive index generated by refractive index anisotropy of the region R and the thickness of the optically-anisotropic layer. Here, the difference in refractive index generated by refractive index anisotropy of the region R in the optically-anisotropic layer is defined by a difference between a refractive index of a direction of an in-plane slow axis of the region R and a refractive index of a direction orthogonal to the direction of the slow axis. That is, the difference Δn in refractive index generated by refractive index anisotropy of the region R is the same as a difference between a refractive index of the liquid crystal compound 34 in the direction of the optical axis 34A and a refractive index of the liquid crystal compound 34 in a direction perpendicular to the optical axis 34A in a plane of the region R. That is, the difference Δn in refractive index is the same as the difference in refractive index of the liquid crystal compound.

In the optical element 30 having the liquid crystal alignment pattern where the optical axis 34A continuously rotates in the one direction in a radial shape, the region where the orientations of the optical axes 34A are the same that is formed in an annular shape where the centers match with each other corresponds to the region R in FIG. 15. Regarding this point, the same can also be applied to the reflective optical element 30 including a cholesteric liquid crystal layer described below.

In a case where circularly polarized light is incident into the above-described optically-anisotropic layer 32A, the light is refracted such that the direction of the circularly polarized light is converted.

This action is schematically shown in FIGS. 16 and 17. In the optically-anisotropic layer 32A, the value of the product of the difference in refractive index of the liquid crystal compound and the thickness of the optically-anisotropic layer is λ/2.

As described above, this action is also completely the same in the optical element 30 having the liquid crystal alignment pattern where the optical axis 34A continuously rotates in the one direction in a radial shape.

As shown in FIG. 16, in a case where the value of the product of the difference in refractive index of the liquid crystal compound in the optically-anisotropic layer 32 and the thickness of the optically-anisotropic layer is λ/2 and incidence light L₁ as left circularly polarized light is incident into the optically-anisotropic layer 32, the incidence light L₁ transmits through the optically-anisotropic layer 32A to be imparted with a retardation of 180°, and the transmitted light L₂ is converted into right circularly polarized light.

In addition, in a case where the incidence light L₁ transmits through the optically-anisotropic layer 32A, an absolute phase thereof changes depending on the orientation of the optical axis 34A of each of the liquid crystal compounds 34. In this case, the orientation of the optical axis 34A changes while rotating in the arrow A direction. Therefore, the amount of change in the absolute phase of the incidence light L₁ varies depending on the orientation of the optical axis 34A. Further, the liquid crystal alignment pattern that is formed in the optically-anisotropic layer 32A is a pattern that is periodic in the arrow A direction. Therefore, as shown in FIG. 16, the incidence light L₁ transmitted through the optically-anisotropic layer 32 is imparted with an absolute phase Q1 that is periodic in the arrow A direction corresponding to the orientation of each of the optical axes 34A. As a result, an equiphase surface E1 that is tilted in a direction opposite to the arrow A direction is formed.

Therefore, the transmitted light L₂ is refracted (diffracted) to be tilted in a direction perpendicular to the equiphase surface E1 and travels in a direction different from a traveling direction of the incidence light L₁. This way, the incidence light L₁ of the left circularly polarized light is converted into the transmitted light L₂ of right circularly polarized light that is tilted by a predetermined angle in the arrow A direction with respect to an incidence direction. [0102] elliptic annular shape, as schematically shown in FIG. 17, in a case where the value of the product of the difference in refractive index of the liquid crystal compound in the optically-anisotropic layer 32A and the thickness of the optically-anisotropic layer is λ/2 and incidence light L₄ as right circularly polarized light is incident into the optically-anisotropic layer 32A, the incidence light L₄ transmits through the optically-anisotropic layer 32 to be imparted with a retardation of 180° and is converted into transmitted light L₅ of left circularly polarized light.

In addition, in a case where the incidence light L₄ transmits through the optically-anisotropic layer 32A, an absolute phase thereof changes depending on the orientation of the optical axis 34A of each of the liquid crystal compounds 34. In this case, the orientation of the optical axis 34A changes while rotating in the arrow A direction. Therefore, the amount of change in the absolute phase of the incidence light L₄ varies depending on the orientation of the optical axis 34A. Further, the liquid crystal alignment pattern that is formed in the optically-anisotropic layer 32A is a pattern that is periodic in the arrow A direction. Therefore, as shown in FIG. 17, the incidence light L₄ transmitted through the optically-anisotropic layer 32 is imparted with an absolute phase Q2 that is periodic in the arrow A direction corresponding to the orientation of each of the optical axes 34A.

Here, the incidence light L₄ is right circularly polarized light. Therefore, the absolute phase Q2 that is periodic in the arrow A direction corresponding to the orientation of the optical axis 34A is opposite to the incidence light L₁ as left circularly polarized light. As a result, in the incidence light L₄, an equiphase surface E2 that is tilted in the arrow A direction opposite to that of the incidence light L₁ is formed.

Therefore, the incidence light L₄ is refracted to be tilted in a direction perpendicular to the equiphase surface E2 and travels in a direction different from a traveling direction of the incidence light L₄. This way, the incidence light L₄ is converted into the transmitted light L₅ of left circularly polarized light that is tilted by a predetermined angle in a direction opposite to the arrow A direction with respect to an incidence direction.

In the optically-anisotropic layer 32, it is preferable that the in-plane retardation value of the plurality of regions R is a half wavelength. It is preferable that an in-plane retardation Re(550)=Δn₅₅₀×d of the plurality of regions R of the optically-anisotropic layer 32 with respect to the incidence light having a wavelength of 550 nm is in a range defined by the following Expression (1). Here, Δn₅₅₀ represents a difference in refractive index generated by refractive index anisotropy of the region R in a case where the wavelength of incidence light is 550 nm, and d represents the thickness of the optically-anisotropic layer 32.

$$200 nm \leq Δ {n}_{550} \times d \leq 350 nm \qquad ( 1 )$$

The optically-anisotropic layer 32 functions as a so-called λ/2 plate. However, in the present invention, in a case where the support 27 and the photo-alignment film 28b are provided, the optically-anisotropic layer 32 includes an aspect where a laminate integrally including the support 27 and the photo-alignment film 28b functions as a λ/2 plate.

Here, by changing the single period Λ of the liquid crystal alignment pattern formed in the optically-anisotropic layer 32A, refraction angles of the transmitted light components L₂ and L₅ can be adjusted. Specifically, as the single period Λ of the liquid crystal alignment pattern decreases, light components transmitted through the liquid crystal compounds 34 adjacent to each other more strongly interfere with each other. Therefore, the transmitted light components L₂ and L₅ can be more largely refracted. Therefore, for example, the interval of the exposure patterns Pr decreases such that the single period Λ decreases.

In addition, refraction angles of the transmitted light components L₂ and L₅ with respect to the incidence light components L₁ and L₄ vary depending on the wavelengths of the incidence light components L₁ and L₄ (the transmitted light components L₂ and L₅). Specifically, as the wavelength of incidence light increases, the transmitted light is largely refracted. That is, in a case where incidence light is red light, green light, and blue light, the red light is refracted to the highest degree, and the blue light is refracted to the lowest degree.

Further, by reversing the rotation direction of the optical axis 34A of the liquid crystal compound 34 that rotates in the arrow A direction, the refraction direction of transmitted light can be reversed.

As described above, in the optically-anisotropic layer 32 of the optical element 30, in the liquid crystal alignment pattern in which the optical axis 34A rotates in the one direction, the single period Λ of the liquid crystal alignment pattern gradually decreases from the inner side (center) toward the outer side.

Accordingly, depending on the wavelength, the polarization state, and the like of incident light, the rotation direction of the optical axis 34A from an inner side toward an outer side is set such that light is refracted from the center of the optical element 30, and the degree to which the length of the single period Λ of the liquid crystal alignment pattern gradually decreases is appropriately adjusted. As a result, the degree to which the light is focused toward the center (optical axis) of the optical element 30 can be adjusted.

That is, by increasing the degree to which the length of the single period Λ in the liquid crystal alignment pattern gradually decreases, the optical element 30 can act as a condenser lens (convex lens). In addition, by decreasing the degree to which the length of the single period Λ in the liquid crystal alignment pattern gradually decreases, the optical element 30 can act as a collimating lens.

Here, according to the present invention, for example, as shown in FIGS. 4, 9, and 11, the plurality of exposure patterns Pr having an annular, elliptic annular, or deformed elliptic annular shape where the center positions are different or match with each other (substantially match with each other) instead of a concentric pattern can be formed. That is, according to the present invention, an optically-anisotropic layer that includes a liquid crystal alignment pattern corresponding to the exposure patterns Pr can be obtained.

Therefore, the present invention is applicable to, for example, a backlight of a liquid crystal display device or an HMD such as AR glasses or VR goggles, and is also suitably applicable to a liquid crystal lens where the diffraction angle varies in the left-right direction and the ways that the refraction of light changes vary.

Regarding this point, the same can also be applied to the reflective optical element described below.

The optically-anisotropic layer 32 is formed of a liquid crystal composition including a rod-like liquid crystal compound or a disk-like liquid crystal compound, and has a liquid crystal alignment pattern in which an optical axis of the rod-like liquid crystal compound or an optical axis of the disk-like liquid crystal compound is aligned as described above.

By forming the photo-alignment film 28b having the alignment pattern corresponding to the above-described liquid crystal alignment pattern on the support 27 and applying the liquid crystal composition to the photo-alignment film 28b, and curing the applied liquid crystal composition, the optically-anisotropic layer formed of the cured layer of the liquid crystal composition can be obtained.

In addition, the liquid crystal composition for forming the optically-anisotropic layer 32 includes a rod-like liquid crystal compound or a disk-like liquid crystal compound and may further include other components such as a leveling agent, an alignment control agent, a polymerization initiator, or an alignment assistant.

In addition, it is preferable that the optically-anisotropic layer 32 has a wide range for the wavelength of incidence light and is formed of a liquid crystal material having a reverse birefringence index dispersion. In addition, it is also preferable that the optically-anisotropic layer can be made to have a substantially wide range for the wavelength of incidence light by imparting a twist component to the liquid crystal composition or by laminating different retardation layers. For example, in the optically-anisotropic layer 32, a method of realizing a λ/2 plate having a wide-range pattern by laminating two liquid crystal layers having different twisted directions is disclosed in, for example, JP2014-089476A and can be preferably used in the present invention.

### —Rod-Like Liquid Crystal Compound—

As the rod-like liquid crystal compound, an azomethine compound, an azoxy compound, a cyanobiphenyl compound, a cyanophenyl ester compound, a benzoate compound, a phenyl cyclohexanecarboxylate compound, a cyanophenylcyclohexane compound, a cyano-substituted phenylpyrimidine compound, an alkoxy-substituted phenylpyrimidine compound, a phenyldioxane compound, a tolan compound, or an alkenylcyclohexylbenzonitrile compound is preferably used. As the rod-like liquid crystal compound, not only the above-described low molecular weight liquid crystal molecules but also high molecular weight liquid crystal molecules can be used.

In the optically-anisotropic layer 32, it is more preferable that the alignment of the rod-like liquid crystal compound is immobilized by polymerization. Examples of the polymerizable rod-like liquid crystal compound include compounds described in Makromol. Chem., (1989), Vol. 190, p. 2255, Advanced Materials (1993), Vol. 5, p. 107, U.S. Pat. Nos. 4,683,327A, 5,622,648A, U.S. Pat. No. 5,770,107A, WO95/22586A, WO95/24455A, WO97/00600A, WO98/23580A, WO98/52905A, JP1989-272551A (JP-H1-272551A), JP1994-16616A (JP-H6-16616A), JP1995-110469A (JP-H7-110469A), JP1999-80081A (JP-H11-80081A), and JP2001-64627A (JP2001-328973A). Further, as the rod-like liquid crystal compound, for example, compounds described in JP1999-513019A (JP-H11-513019A) and JP2007-279688A can also be preferably used.

### —Disk-Like Liquid Crystal Compound—

As the disk-like liquid crystal compound, for example, compounds described in JP2007-108732A and JP2010-244038A can be preferably used.

In a case where the disk-like liquid crystal compound is used in the optically-anisotropic layer, the liquid crystal compound 34 rises in the thickness direction in the optically-anisotropic layer, and the optical axis 34A derived from the liquid crystal compound is defined as an axis perpendicular to a disk plane, that is so-called, a fast axis.

The above-described optical element 30 is a transmissive optical element 30 through which circularly polarized light transmits and is diffracted. However, the optical element manufactured using the exposure method according to the embodiment of the present invention is not limited to this configuration.

That is, the optical element manufactured using the exposure method according to the embodiment of the present invention may be a reflective optical element including a cholesteric liquid crystal layer.

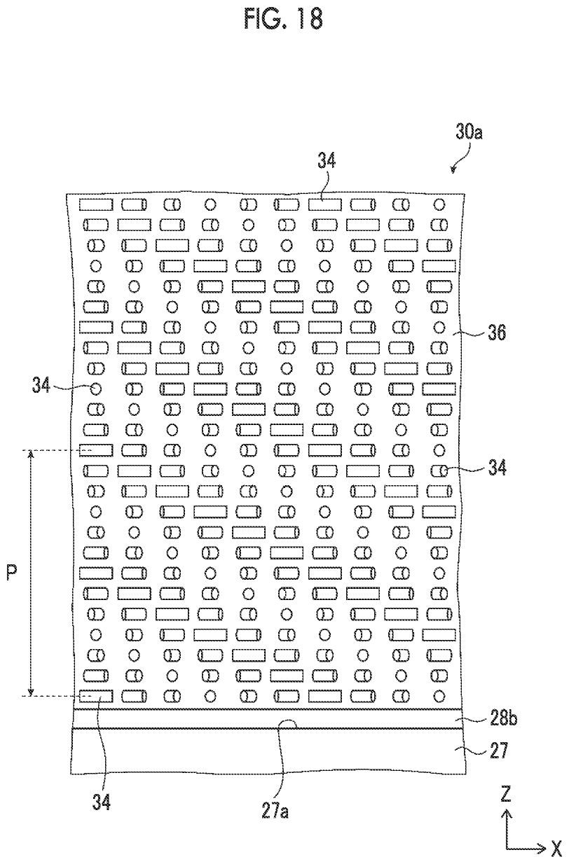

FIG. 18 schematically shows an example of the reflective optical element manufactured using the exposure method according to the embodiment of the present invention. In an optical element 30a shown in FIG. 18, the same components as those of the above-described transmissive optical element 30 are represented by the same reference numerals, and the detailed description thereof will not be repeated.

FIG. 18 is a diagram schematically showing a layer configuration of the reflective optical element 30a. The optical element 30a includes the support 27 and the photo-alignment film 28b described above, and further includes a cholesteric liquid crystal layer 36 that exhibits the action as the reflective optical element 30a.

Regarding the liquid crystal alignment pattern of the liquid crystal compound 34 in the cholesteric liquid crystal layer 36, as in the optical element 30, as shown in FIG. 13, the liquid crystal alignment pattern in which the optical axis 34A changes while continuously rotating in the one direction indicated by the arrow A is provided in a radial shape.

FIG. 19 is a schematic diagram showing an alignment state of the liquid crystal compound 34 in a plane of a main surface of the cholesteric liquid crystal layer 36. FIG. 19 shows an alignment state of a facing surface of a cholesteric liquid crystal layer 36A facing the photo-alignment film 28b.

As in FIG. 15, in the cholesteric liquid crystal layer 36A shown in FIG. 19, in order to describe the cholesteric liquid crystal layer 36, the liquid crystal alignment pattern in which the optical axis 34A changes while continuously rotating in the one direction indicated by the arrow A is shown. However, even in the liquid crystal alignment pattern that includes one direction in which the optical axis changes while continuously rotating in a radial shape (concentric shape) from an inner side toward an outer side, the same optical effects as those of the liquid crystal alignment pattern shown in FIG. 19 can be exhibited for the one direction in which the optical axis changes while continuously rotating.

In addition, as in FIG. 15, even in FIG. 19, a circumferential direction of a concentric circle in the concentric liquid crystal alignment pattern shown in FIG. 13 corresponds to the Y direction in FIG. 19.

As shown in FIG. 18, the cholesteric liquid crystal layer 36 is a layer obtained by cholesteric alignment of the liquid crystal compound 34. In addition, FIGS. 18 and 19 show an example in which the liquid crystal compound forming the cholesteric liquid crystal layer is a rod-like liquid crystal compound.

In the following description, the cholesteric liquid crystal layer will also be referred to as “liquid crystal layer”.

In the optical element 30a, the support 27 and the photo-alignment film 28b are as described above.

In the optical element 30a, the liquid crystal layer 36 (cholesteric liquid crystal layer) having the liquid crystal alignment pattern shown in FIG. 13 is provided on the photo-alignment film 28b having the alignment pattern shown in FIG. 13.

The liquid crystal layer 36 is a cholesteric liquid crystal layer obtained by cholesterically aligning the liquid crystal compound to immobilize a cholesteric liquid crystal phase. In the present example, the cholesteric liquid crystal layer has a liquid crystal alignment pattern in which an orientation of an optical axis derived from a liquid crystal compound changes while continuously rotating in at least one in-plane direction.

As schematically shown in FIG. 18, the liquid crystal layer 36 has a helical structure in which the liquid crystal compound 34 is helically turned and laminated as in a cholesteric liquid crystal layer obtained by immobilizing a typical cholesteric liquid crystal phase. In the helical structure, a configuration in which the liquid crystal compound 34 is helically rotated once (rotated by 360°) and laminated is set as one helical pitch (helical pitch P), and plural pitches of the helically turned liquid crystal compound 34 are laminated.

As is well known, the cholesteric liquid crystal phase exhibits selective reflectivity with respect to left or right circularly polarized light at a specific wavelength. Whether or not the reflected light is right circularly polarized light or left circularly polarized light is determined depending on a helical twisted direction (sense) of the cholesteric liquid crystal phase. Regarding the selective reflection of the circularly polarized light by the cholesteric liquid crystal phase, in a case where the helical twisted direction of the cholesteric liquid crystal phase is right, right circularly polarized light is reflected, and in a case where the helical twisted direction of the cholesteric liquid crystal phase is left, left circularly polarized light is reflected.

A turning direction of the cholesteric liquid crystal phase can be adjusted by adjusting the kind of the liquid crystal compound that forms the cholesteric liquid crystal layer and/or the kind of the chiral agent to be added.

In addition, a half-width Δλ (nm) of a selective reflection range (circularly polarized light reflection range) where selective reflection is exhibited depends on Δn of the cholesteric liquid crystal phase and the helical pitch P and satisfies a relationship of “Δλ=Δn×helical pitch”. Therefore, the width of the selective reflection range can be controlled by adjusting Δn. Δn can be adjusted by adjusting a kind of a liquid crystal compound for forming the cholesteric liquid crystal layer and a mixing ratio thereof, and a temperature during alignment immobilization.

Accordingly, regarding the wavelength of light that is reflected (diffracted) by the liquid crystal layer 36, the selective reflection wavelength range of the liquid crystal layer may be appropriately set, for example, by adjusting the helical pitch P of the liquid crystal layer 36.

As shown in FIG. 19, in the liquid crystal layer 36, the liquid crystal compounds 34 are arranged in the arrow A direction and the Y direction orthogonal to the arrow A direction. The orientation of the optical axis 34A of the liquid crystal compound 34 changes while continuously rotating in the one direction in a plane, that is, in the arrow A direction. In addition, in the Y direction, the liquid crystal compounds 34 in which the orientations of the optical axes 34A are the same are aligned at regular intervals.

“The orientation of the optical axis 34A of the liquid crystal compound 34 changes while continuously rotating in the one in-plane direction” represents that as in the optically-anisotropic layer 32, angles between the optical axes 34A of the liquid crystal compounds 34 and the arrow A direction vary depending on positions in the arrow A direction and the angle between the optical axis 34A and the arrow A direction gradually changes from θ to θ+180° or θ−180° in the arrow A direction. That is, in each of the plurality of liquid crystal compounds 34 arranged in the arrow A direction, as shown in FIG. 19, the optical axis 34A changes in the arrow A direction while rotating on a given angle basis.

A difference between the angles of the optical axes 34A of the liquid crystal compounds 34 adjacent to each other in the arrow A direction is preferably 45° or less, more preferably 15° or less, and still more preferably less than 15°.

As in the above-described optically-anisotropic layer 32, even in the liquid crystal layer 36, in the liquid crystal alignment pattern of the liquid crystal compound 34, a length (distance) over which the optical axis 34A of the liquid crystal compound 34 rotates by 180° in the arrow A direction in which the optical axis 34A changes while continuously rotating in a plane is set as a length Λ of the single period in the liquid crystal alignment pattern.

In the liquid crystal alignment pattern of the liquid crystal layer 36, the single period Λ is repeated in the arrow A direction, that is, in the one direction in which the orientation of the optical axis 34A changes while continuously rotating. The optical element 30a is a liquid crystal diffraction element, and the single period Λ is the period (single period) of the diffraction structure as described above.

On the other hand, in the liquid crystal compound 34 forming the liquid crystal layer 36, the orientations of the optical axes 34A are the same in the direction (in FIG. 19, the Y direction) orthogonal to the arrow A direction, that is, the Y direction orthogonal to the one direction in which the optical axis 34A continuously rotates. In the liquid crystal alignment pattern shown in FIG. 13, as described above, the Y direction is a circumferential direction of a concentric circle.

In other words, in the liquid crystal compound 34 forming the liquid crystal layer 36, angles between the optical axes 34A of the liquid crystal compound 34 and the arrow A direction (X direction) are the same in the Y direction.

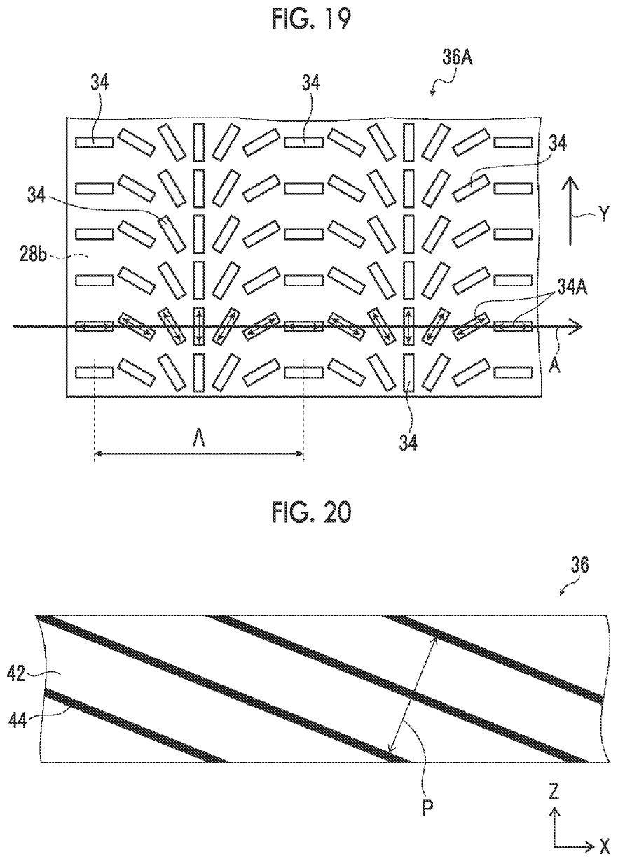

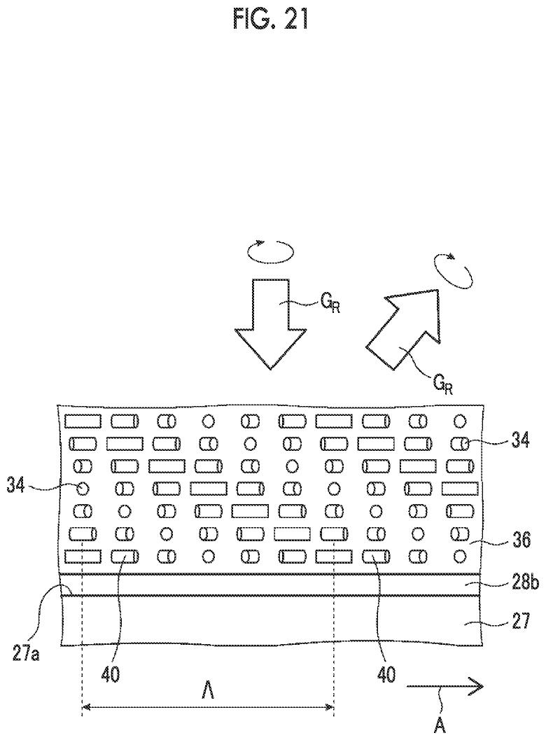

In a case where a cross section of the liquid crystal layer 36 in the X-Z direction shown in FIG. 18 is observed with a scanning electron microscope (SEM), an arrangement direction in which bright portions 42 and dark portions 44 are alternately arranged as shown in FIG. 20, a stripe pattern tilted at a predetermined angle with respect to the main surface (X-Y plane) is observed.

Basically, the interval of the bright portions 42 and the dark portions 44 depends on the helical pitch P of the cholesteric liquid crystal layer.

Accordingly, the wavelength range of light that is selectively reflected by the cholesteric liquid crystal layer correlates to the interval of the bright portions 42 and the dark portions 44. That is, as the interval of the bright portions 42 and the dark portions 44 increases, the helical pitch P increases. Therefore, the wavelength range of light that is selectively reflected by the cholesteric liquid crystal layer increases. Conversely, as the interval of the bright portions 42 and the dark portions 44 decreases, the helical pitch P decreases. Therefore, the wavelength range of light that is selectively reflected by the cholesteric liquid crystal layer decreases.

In the cholesteric liquid crystal layer, basically, a structure in which the bright portion 42 and the dark portion 44 are repeated twice corresponds to the helical pitch P. Accordingly, in the cross section observed with a scanning electron microscope, an interval between the bright portions 42 adjacent to each other or between the dark portions 44 adjacent to each other in a normal direction (vertical direction) of lines formed by the bright portions 42 or the dark portions 44 corresponds to a ½ pitch of the helical pitch P.

That is, the helical pitch P may be measured by setting the interval between the bright portions 42 or between the dark portions 44 in the normal direction with respect to the lines as a ½ pitch.

Hereinafter, an action of diffraction of the liquid crystal layer 36 will be described.

In a cholesteric liquid crystal layer of the related art, a helical axis derived from a cholesteric liquid crystal phase is perpendicular to the main surface, and a reflecting surface thereof is parallel to the main surface. In addition, the optical axis of the liquid crystal compound is not tilted with respect to the main surface. In other words, the optical axis is parallel to the main surface. Accordingly, in a case where the X-Z plane of the cholesteric liquid crystal layer in the related art is observed with a scanning electron microscope, an arrangement direction in which bright portions and dark portions are alternately arranged is perpendicular to the main surface.

The cholesteric liquid crystal phase has specular reflectivity. Therefore, in a case where light is incident from the normal direction into the cholesteric liquid crystal layer, the light is reflected in the normal direction.

On the other hand, the liquid crystal layer 36 reflects incident light in a state where the light is tilted in the arrow A direction with respect to the specular reflection. The liquid crystal layer 36 has the liquid crystal alignment pattern in which the optical axis 34A changes while continuously rotating in the arrow A direction (the predetermined one direction) in a plane. Hereinafter, the description will be made with reference to FIG. 21.

For example, it is assumed that the liquid crystal layer 36 is a cholesteric liquid crystal layer that selectively reflects right circularly polarized light GR of green light. Accordingly, in a case where light is incident into the liquid crystal layer 36, the liquid crystal layer 36 reflects only right circularly polarized light GR of green light and allows transmission of the other light.

Here, in the liquid crystal layer 36, the optical axis 34A of the liquid crystal compound 34 changes while rotating in the arrow A direction (the one direction).

The liquid crystal alignment pattern formed in the liquid crystal layer 36 is a pattern that is periodic in the arrow A direction. Therefore, as schematically shown in FIG. 21, the right circularly polarized light GR of green light incident into the liquid crystal layer 36 is reflected (diffracted) in a direction corresponding to the period of the liquid crystal alignment pattern, and the reflected right circularly polarized light of red light is reflected (diffracted) in a direction tilted with respect to the XY plane (the main surface of the cholesteric liquid crystal layer) in the arrow A direction.

In addition, in a case where circularly polarized light having the same wavelength and the same turning direction is reflected, by reversing the rotation direction of the optical axis 34A of the liquid crystal compound 34 toward the arrow A direction, a reflection direction of the circularly polarized light can be reversed.

That is, in FIGS. 18 and 19, the rotation direction of the optical axis 34A toward the arrow A direction is clockwise, and one circularly polarized light is reflected in a state where the light is tilted in the arrow A direction. By setting the rotation direction of the optical axis 34A to be counterclockwise, the circularly polarized light is reflected in a state where the light is tilted in a direction opposite to the arrow A direction.

Further, in the liquid crystal layer having the same liquid crystal alignment pattern, the reflection direction is reversed by adjusting the helical turning direction of the liquid crystal compound 34, that is, the turning direction of circularly polarized light to be reflected.

For example, in a case where the helical turning direction of the liquid crystal layer is right-twisted, the liquid crystal layer selectively reflects right circularly polarized light, and has the liquid crystal alignment pattern in which the optical axis 34A rotates clockwise in the arrow A direction. As a result, the right circularly polarized light is reflected in a state where the light is tilted in the arrow A direction.

In addition, for example, in a case where the helical turning direction of the liquid crystal layer is left-twisted, the liquid crystal layer selectively reflects left circularly polarized light, and has the liquid crystal alignment pattern in which the optical axis 34A rotates clockwise in the arrow A direction. As a result, the left circularly polarized light is reflected in a state where the light is tilted in a direction opposite to the arrow A direction.

Accordingly, the optical element 30a can be used as a convex mirror that reflects incidence light to diffuse the light or a concave mirror that reflects incidence light to focus the light depending on the rotation direction of the optical axis 34A from the inner side toward the outer side in the liquid crystal layer 36 and the turning direction of circularly polarized light to be selectively reflected from the liquid crystal layer 36.

As described above, in the liquid crystal layer 36 that acts as the reflective optical element 30a, in the liquid crystal alignment pattern of the liquid crystal compound 34, the single period A as the length over which the optical axis 34A of the liquid crystal compound 34 rotates by 180° is the period (single period) of the diffraction structure. In addition, in the liquid crystal layer 36, the one direction (arrow A direction) in which the optical axis 34A of the liquid crystal compound 34 changes while rotating is the periodic direction of the diffraction structure.

In the liquid crystal layer having the liquid crystal alignment pattern, as the single period Λ decreases, the diffraction angle of reflected light with respect to the incidence light increases. That is, as the single period Λ decreases, incidence light can be largely diffracted to be reflected in a direction that is largely different from specular reflection.

The single period Λ of the liquid crystal layer 36 is not particularly limited, and the single period Λ from which signal light 103 to be assumed can be separated may be appropriately set depending on the wavelength or the like of the signal light 103.

The single period Λ of the liquid crystal layer 36 is preferably 0.1 to 20 μm and more preferably 0.1 to 10 μm.

The liquid crystal layer 36 can be formed by immobilizing a liquid crystal phase in a layer shape, the liquid crystal phase obtained by aligning the liquid crystal compound 34 in a predetermined alignment state. For example, the cholesteric liquid crystal layer can be formed by immobilizing a cholesteric liquid crystal phase in a layer shape.

The structure in which a cholesteric liquid crystal phase is immobilized may be a structure in which the alignment of the liquid crystal compound as a liquid crystal phase is maintained. Typically, it is preferable that the structure in which a cholesteric liquid crystal phase is immobilized is a structure which is obtained by making the polymerizable liquid crystal compound to be in a predetermined alignment state of a liquid crystal phase, polymerizing and curing the polymerizable liquid crystal compound with ultraviolet irradiation, heating, or the like to form a layer having no fluidity, and concurrently changing the state of the polymerizable liquid crystal compound into a state where the alignment state is not changed by an external field or an external force.

The structure in which a liquid crystal phase is immobilized is not particularly limited as long as the optical characteristics of the liquid crystal phase are maintained, and the liquid crystal compound 34 in the liquid crystal layer does not necessarily exhibit liquid crystallinity. For example, the molecular weight of the polymerizable liquid crystal compound may be increased by a curing reaction such that the liquid crystallinity thereof is lost.

Regarding this point, the same can also be applied to the above-described optically-anisotropic layer 32.

Examples of a material used for forming the liquid crystal layer 36 include a liquid crystal composition including a liquid crystal compound. It is preferable that the liquid crystal compound is a polymerizable liquid crystal compound.

Examples of the liquid crystal composition for forming the liquid crystal layer 36 include a liquid crystal composition obtained by adding a chiral agent for helically aligning the liquid crystal compound 34 to the liquid crystal composition for forming the optically-anisotropic layer 32 of the above-described transmissive optical element 30a.

### ——Chiral Agent (Optically Active Compound)——

The chiral agent has a function of causing a helical structure of a cholesteric liquid crystal phase to be formed. The chiral agent may be selected depending on the purpose because a helical twisted direction or a helical pitch P derived from the compound varies.

The chiral agent is not particularly limited, and a well-known compound (for example, Liquid Crystal Device Handbook (No. 142 Committee of Japan Society for the Promotion of Science, 1989), Chapter 3, Article 4-3, chiral agent for twisted nematic (TN) or super twisted nematic (STN), p. 199), isosorbide, or an isomannide derivative can be used.

In general, the chiral agent includes a chiral carbon atom. However, an axially chiral compound or a planar chiral compound not having a chiral carbon atom can also be used as the chiral agent. Examples of the axially chiral compound or the planar chiral compound include binaphthyl, helicene, paracyclophane, and derivatives thereof. The chiral agent may include a polymerizable group. In a case where both the chiral agent and the liquid crystal compound have a polymerizable group, a polymer which includes a repeating unit derived from the polymerizable liquid crystal compound and a repeating unit derived from the chiral agent can be formed due to a polymerization reaction of a polymerizable chiral agent and the polymerizable liquid crystal compound. In this aspect, it is preferable that the polymerizable group in the polymerizable chiral agent is the same as the polymerizable group in the polymerizable liquid crystal compound. Accordingly, the polymerizable group of the chiral agent is preferably an unsaturated polymerizable group, an epoxy group, or an aziridinyl group, more preferably an unsaturated polymerizable group, and still more preferably an ethylenically unsaturated polymerizable group.

In addition, the chiral agent may be a liquid crystal compound.

In a case where the chiral agent includes a photoisomerization group, a pattern having a desired reflection wavelength corresponding to a luminescence wavelength can be formed by irradiation of an actinic ray or the like through a photomask after coating and alignment, which is preferable. As the photoisomerization group, an isomerization portion of a photochromic compound, an azo group, an azoxy group, or a cinnamoyl group is preferable. Specific examples of the compound include compounds described in JP2002-80478A, JP2002-80851A, JP2002-179668A, JP2002-179669A, JP2002-179670A, JP2002-179681A, JP2002-179682A, JP2002-338575A, JP2002-338668A, JP2003-313189A, and JP2003-313292A.

The content of the chiral agent in the liquid crystal composition is preferably 0.01 to 200 mol % and more preferably 1 to 30 mol % with respect to the content molar amount of the liquid crystal compound.

In a case where the liquid crystal layer 36 is formed, it is preferable that the liquid crystal layer 36 is formed by applying the liquid crystal composition to a surface where the liquid crystal layer 36 is to be formed, aligning the liquid crystal compound 34 to a state of a desired liquid crystal phase, and curing the liquid crystal compound 34.

That is, in a case where the cholesteric liquid crystal layer 34 is formed on the photo-alignment film 28b, it is preferable that the liquid crystal layer 36 is formed by applying the liquid crystal composition to the photo-alignment film 28b, aligning the liquid crystal compound 34 to a state of a cholesteric liquid crystal phase, and curing the liquid crystal compound 34 to immobilize a cholesteric liquid crystal phase.

The applied liquid crystal composition is optionally dried and/or heated and then is cured to form the liquid crystal layer. In the drying and/or heating step, the liquid crystal compound 34 in the liquid crystal composition only has to be aligned to a cholesteric liquid crystal phase. In the case of heating, the heating temperature is preferably 200° C. or lower and more preferably 130° C. or lower.

The aligned liquid crystal compound 34 is optionally further polymerized. Regarding the polymerization, thermal polymerization or photopolymerization using light irradiation may be performed, and photopolymerization is preferable. Regarding this point, the same can also be applied to the above-described optically-anisotropic layer 32.

Regarding the light irradiation, ultraviolet light is preferably used. The irradiation energy is preferably 20 mJ/cm² to 50 J/cm² and more preferably 50 to 1500 mJ/cm². In order to promote a photopolymerization reaction, light irradiation may be performed under heating conditions or in a nitrogen atmosphere. The wavelength of irradiated ultraviolet light is preferably 250 to 430 nm.

The thickness of the liquid crystal layer 36 is not particularly limited, and the thickness with which a required light reflectivity can be obtained may be appropriately set depending on the use of the diffraction element, the light reflectivity required for the liquid crystal layer, the material for forming the liquid crystal layer 36, and the like.

Basically, the present invention is configured as described above. Hereinabove, the exposure method and the exposure device, and the method of forming an optically-anisotropic layer according to the present invention have been described in detail. However, the present invention is not limited to the above-described embodiment, and various improvements and modifications can be made within a range not departing from the scope of the present invention.

### EXAMPLES

Hereinafter, the characteristics of the present invention will be described in detail using examples. Materials, reagents, amounts thereof, proportions thereof, operations, and the like shown in the following examples can be appropriately changed as long as they do not depart from the scope of the present invention. Accordingly, the scope of the present invention is not limited to the following examples.

### Example 1

### (Support)

A glass substrate was used as the support.

### (Formation of Alignment Film)

The following coating liquid for forming an alignment film was applied to the support by spin coating. The support on which the coating film of the coating liquid for forming an alignment film was formed was dried using a hot plate at 60ºC for 60 seconds. As a result, an alignment film was formed.

Coating Liquid for forming Alignment Film

| | | |
|---|---|---|
| Material A for photo-alignment | 1.00 | part by mass |
| Water | 16.00 | parts by mass |
| Butoxyethanol | 42.00 | parts by mass |
| Propylene glycol monomethyl ether | 42.00 | parts by mass |

Material A for Photo-Alignment

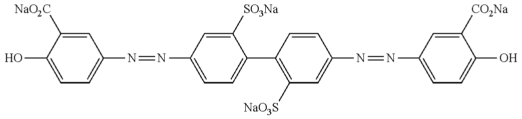

### (Exposure of Alignment Film)

Using the exposure device having the configuration shown in FIG. 1, the alignment film (photo-alignment film) was exposed.

As the light source unit, the above-described unit that emits laser light of linearly polarized light having a wavelength of 355 nm was used, and the exposure amount thereof was 1000 mJ/cm².

As the optical member, an axicon lens was used, and the optical axis direction (x direction) matched with the horizontal direction.

The alignment film was held such that the main surface was orthogonal to the optical axis direction (x direction) of the axicon lens in a state where it stood in the vertical direction (z direction).

The movement direction of the alignment film had an angle of 10° with respect to the x direction in a case where the x-y plane including the optical axis of the axicon lens was the horizontal plane (angle α=10°).

As the axicon lens, a lens where the angle θ between the bottom surface and the generatrix of the cone was 20° was used.

The rotation speed of the rotating unit that rotates the λ/2 plate was fixed to 30°/sec.

In a case where the distance from the x-coordinate of the vertex of the axicon lens to the x-coordinate of the alignment film on the optical axis of the axicon lens in the positive x direction of the moving unit was represented by DL, a movement start point was DL=150 mm, and a movement end point was DL=1 mm.

The movement speed of the alignment film was set to 0.27 μm/sec at the movement start point and 2.83 μm/sec at the movement end point, and the movement speed therebetween was set to linearly increase.

### (Formation of Optically-Anisotropic Layer)

As the liquid crystal composition forming the optically-anisotropic layer, the following liquid crystal composition was prepared.

Liquid Crystal Composition

| | | |
|---|---|---|
| Liquid crystal compound L-1 | 100.00 | parts by mass |
| Polymerization initiator (IRGACURE OXE01, manufactured by BASF SE) | 1.00 | part by mass |
| Leveling agent T-1 | 0.08 | parts by mass |
| Methyl ethyl ketone | 1050.00 | parts by mass |

Liquid Crystal Compound L-1 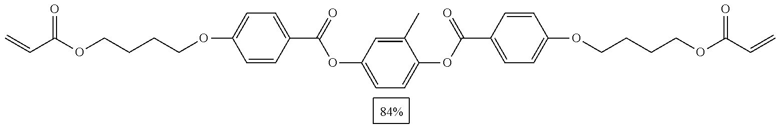 [SMILES: C=CC(=O)OCCCCOc1ccc(C(=O)Oc2ccc(OC(=O)c3ccc(OCCCCOC(=O)C=C)cc3)c(C)c2)cc1] 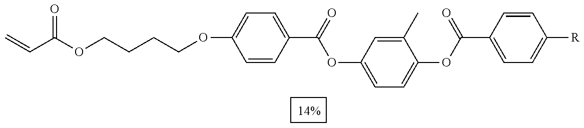 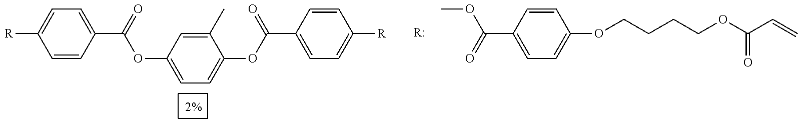
Leveling Agent T-1

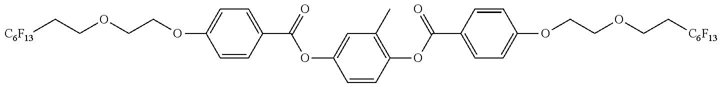

The above-described liquid crystal composition was applied to the exposed alignment film to form a coating film, and the coating film was heated using a hot plate at 80° C. Next, the coating film was irradiated with ultraviolet light having a wavelength of 365 nm at an irradiation dose of 300 mJ/cm² using a high pressure mercury lamp in a nitrogen atmosphere. As a result, the alignment of the liquid crystal compound was immobilized.

This way, an optical element where the alignment film and the optically-anisotropic layer were laminated in this order on the glass substrate was obtained.

In a case where the manufactured optical element was observed with an optical microscope, the liquid crystal alignment pattern that was one-axis symmetrical with respect to the y direction as the symmetrical axis as shown in FIG. 4 was verified in the optically-anisotropic layer.

This liquid crystal alignment pattern had a plurality of circular-ring shaped, that is, annular patterns having different diameters. In addition, in one annular pattern, optical axes derived from the liquid crystal compound faced the same direction.

Specifically, as shown in FIG. 4, annular patterns having large diameters sequentially encompassed annular patterns having small diameters. In addition, in the annular patterns, the centers positions matched with each other in the z direction, that is, the vertical direction during the exposure, and were different from each other in the y direction, that is, the horizontal direction during the exposure. In the annular patterns, the center position in the y direction moved in the y direction, that is, in the movement direction of the alignment film, and the interval (pitch) of the annuli were sequentially spread out in the y direction.

### Example 2

The exposure of the alignment film was performed using the exposure device having the configuration shown in FIG. 8 where the stage supported the alignment film such that where the normal line of the alignment film was tilted with respect to the optical axis of the axicon lens and the movement direction of the alignment film was the optical axis direction of the axicon lens.

The angle between the optical axis of the axicon lens and the normal line of the alignment film was 10° (angle β=10°).

Using the same method as that of Example 1 except for the above-described conditions, an alignment film (photo-alignment film) was formed, the alignment film was exposed under the same conditions, an optically-anisotropic layer was formed using the same method, and an optical element where the alignment film and the optically-anisotropic layer were laminated in this order on the glass substrate was manufactured.

In a case where the manufactured optical element was observed with an optical microscope, the liquid crystal alignment pattern that was one-axis symmetrical with respect to the y direction as the symmetrical axis as shown in FIG. 9 was verified in the optically-anisotropic layer.

This liquid crystal alignment pattern had a plurality of patterns having a deformed elliptical ring shape, that is, a deformed elliptic annular shape where the minor axis gradually decreased in one major axis direction. In addition, in one annular pattern having a deformed elliptic annular shape, optical axes derived from the liquid crystal compound faced the same direction.

Specifically, as shown in FIG. 9, larger patterns having a deformed elliptic annular shape sequentially encompassed smaller patterns having a deformed elliptic annular shape. In addition, in the patterns having a deformed elliptic annular shape, the centers positions matched with each other in the z direction, that is, the vertical direction during the exposure, and were also substantially the same in the y direction, that is, the horizontal direction during the exposure.

### Example 3

The exposure of the alignment film was performed using the exposure device having the configuration shown in FIG. 10 where the axicon lens was disposed such that the optical axis of the axicon lens was tilted with respect to the optical axis of the light source unit and the movement direction of the alignment film was a direction parallel to the optical axis of the light source unit. That is, the linearly polarized light from the light source unit was incident into the axicon lens from the direction tilted with respect to the optical axis of the axicon lens, and the alignment film was moved in the direction parallel to the incidence direction of the linearly polarized light into the axicon lens to expose the alignment film.

The angle between the optical axis of the light source unit, that is, the incidence direction of the linearly polarized light into the axicon lens and the optical axis of the axicon lens was 10° (angle γ=10°).

Using the same method as that of Example 1 except for the above-described conditions, an alignment film (photo-alignment film) was formed, the alignment film was exposed under the same conditions, an optically-anisotropic layer was formed using the same method, and an optical element where the alignment film and the optically-anisotropic layer were laminated in this order on the glass substrate was manufactured.

In this example, the distance DL is not the distance on the optical axis of the axicon lens but the distance in the optical axis direction of the light source unit, that is, the movement direction of the light source unit from the position of the x-coordinate of the vertex of the axicon lens to the position of the x-coordinate of the alignment film.

In a case where the manufactured optical element was observed with an optical microscope, the liquid crystal alignment pattern that was one-axis symmetrical with respect to the y direction as the symmetrical axis as shown in FIG. 11 was verified in the optically-anisotropic layer.

This liquid crystal alignment pattern had a plurality of patterns having a deformed elliptical ring shape, that is, a deformed elliptic annular shape where the minor axis gradually decreased in one major axis direction. In addition, in one annular pattern having a deformed elliptic annular shape, optical axes derived from the liquid crystal compound faced the same direction.

Specifically, as shown in FIG. 11, larger patterns having a deformed elliptic annular shape sequentially encompassed smaller patterns having a deformed elliptic annular shape. In addition, in the patterns having a deformed elliptic annular shape, the center positions matched with each other in the z direction, that is, in the vertical direction during the exposure. However, in the patterns having a deformed elliptic annular shape, the center positions were shifted from each other in the y direction, that is, in the horizontal direction during the exposure, and the patterns having a deformed elliptic annular shape were concentrated in one y direction.

### EXPLANATION OF REFERENCES

10: exposure device
12: light source unit
13: light source portion
14: shutter
16: rotating unit
18: λ/2 plate
19: optical element
20, 23: optical member
20a: emission surface
20b: back surface
21a: vertex
21b: conical surface
22: stage
22a: surface
24: moving unit
25: first optical element
25a, 29a: vertex
25b, 29b: conical surface
25c, 29c: back surface
26: controller
27: support
27a: surface
28: film
28a: surface
28b: photo-alignment film
29: second optical element
30, 30a: optical element
32, 32A: optically-anisotropic layer
34: liquid crystal compound
34A: optical axis
36, 36A: cholesteric liquid crystal layer
42: bright portion
44: dark portion
A: arrow
A₁: arrow
A₂: arrow
A₃: arrow
Ax: arrow
C, CU: optical axis
C_{L}, CU_{L}: optical axis direction
DL: distance
Dm: distance
E1: equiphase surface
E2: equiphase surface
GR: right circularly polarized light
L: laser light
L₁, L₄: incidence light
L₂, L₅ transmitted light
Lc: light
Lp: exposure light
Lr: ring-shaped light
N: normal line
P: helical pitch
P₀: linearly polarized light
Pr: exposure pattern
Q1, Q2: absolute phase
wr. width

What is claimed is:

1. An exposure method comprising:
focusing linearly polarized light in a ring shape with an optical member and exposing a film including a compound having a photo-aligned group,
wherein while rotating a polarization direction of the linearly polarized light,
the film and the optical member are relatively moved in a direction tilted with respect to an optical axis of the optical member.

2. The exposure method according to claim 1,
wherein while maintaining an angle between a normal line of the film and the optical axis of the optical member, the film and the optical member are relatively moved in the direction tilted with respect to the optical axis of the optical member.

3. The exposure method according to claim 1,
wherein while maintaining a normal line of the film and the optical axis of the optical member in parallel, the film and the optical member are relatively moved in the direction tilted with respect to the optical axis of the optical member.

4. The exposure method according to claim 1,
wherein the optical member includes an axicon lens or an axicon mirror.

5. The exposure method according to claim 4,
wherein in a case where an angle between a bottom surface and a generatrix of a cone configuring the axicon lens or the axicon mirror is represented by θ and a refractive index of a material for forming the axicon lens is represented by n,
an angle α between the relative movement direction of the film and the optical member and an optical axis of the axicon lens satisfies
$$α < {sin}^{- 1} ( n \cdot sin θ ) - θ$$
or
an angle α between the relative movement direction of the film and the optical member and an optical axis of the axicon mirror satisfies
$$α < 2 θ .$$

6. An exposure method comprising:
focusing linearly polarized light in a ring shape with an optical member and exposing a film including a compound having a photo-aligned group,
wherein while rotating a polarization direction of the linearly polarized light, and
the film and the optical member are relatively moved in an optical axis direction of the optical member in a state where a normal line of the film is tilted with respect to an optical axis of the optical member.

7. The exposure method according to claim 6,
wherein while maintaining an angle between the normal line of the film and the optical axis of the optical member, the film and the optical member are relatively moved in the optical axis direction of the optical member.

8. The exposure method according to claim 6,
wherein the optical member includes an axicon lens or an axicon mirror.

9. The exposure method according to claim 8,
wherein in a case where an angle between a bottom surface and a generatrix of a cone configuring the axicon lens or the axicon mirror is represented by θ and a refractive index of a material for forming the axicon lens is represented by n,
an angle β between the normal line of the film and an optical axis of the axicon lens satisfies
$$β < 90 - {sin}^{- 1} ( n \cdot sin θ ) + θ .$$
or
an angle β between the normal line of the film and an optical axis of the axicon mirror satisfies
$$β < 90 - 2 θ .$$

10. An exposure method comprising:
focusing linearly polarized light in a ring shape with an optical member and exposing a film including a compound having a photo-aligned group,
wherein the linearly polarized light is incident into the optical member from a direction tilted with respect to an optical axis of the optical member, and
while rotating a polarization direction of the linearly polarized light,
the film and the optical member are relatively moved in the incidence direction of the linearly polarized light into the optical member.

11. The exposure method according to claim 10,
wherein while maintaining an angle between a normal line of the film and the incidence direction of the linearly polarized light into the optical member, the film and the optical member are relatively moved in the incidence direction of the linearly polarized light into the optical member.

12. The exposure method according to claim 10,
wherein while maintaining a normal line of the film and the incidence direction of the linearly polarized light into the optical member in parallel, the film and the optical member are relatively moved in the incidence direction of the linearly polarized light into the optical member.

13. The exposure method according to claim 10,
wherein the optical member includes an axicon lens or an axicon mirror.

14. The exposure method according to claim 13,
wherein in a case where an angle between a bottom surface and a generatrix of a cone configuring the axicon lens or the axicon mirror is represented by θ and a refractive index of a material for forming the axicon lens is represented by n,
an angle γ between an incidence direction of the linearly polarized light into the optical member and an optical axis of the axicon lens satisfies
$${sin}^{- 1} ( n \cdot sin ( θ + γ ) ) - θ - γ > 0$$
or
an angle γ between an incidence direction of the linearly polarized light into the optical member and an optical axis of the axicon mirror satisfies
$$γ < 2 θ .$$

15. The exposure method according to claim 1,
wherein in the relative movement of the film and the optical member, a movement speed is continuously changed.

16. The exposure method according to claim 6,
wherein in the relative movement of the film and the optical member, a movement speed is continuously changed.

17. The exposure method according to claim 10,
wherein in the relative movement of the film and the optical member, a movement speed is continuously changed.

18. The exposure method according to claim 1,
wherein in the rotation in the polarization direction of the linearly polarized light, a rotation speed is continuously changed.

19. The exposure method according to claim 6,
wherein in the rotation in the polarization direction of the linearly polarized light, a rotation speed is continuously changed.

20. The exposure method according to claim 10,
wherein in the rotation in the polarization direction of the linearly polarized light, a rotation speed is continuously changed.
